(19) United States
(12) Patent Application Publication
(10) Pub. No.: US 2025/0377384 A1
(43) Pub. Date: Dec. 11, 2025

(54) MAGNETIC SENSOR CHIP AND MAGNETIC SENSOR MODULE

(71) Applicant: ROHM CO., LTD., Kyoto (JP)

(72) Inventors: Toru HIGUCHI, Kyoto (JP); Eiji KUWAHARA, Kyoto (JP)

(73) Assignee: ROHM CO., LTD., Kyoto (JP)

(21) Appl. No.: 19/227,177

(22) Filed: Jun. 3, 2025

(30) Foreign Application Priority Data
Jun. 10, 2024 (JP) 2024-093936

(51) Int. Cl. G01R 15/18; G01R 35/00

(52) U.S. Cl. CPC G01R 15/181; G01R 35/00

(57) ABSTRACT

A magnetic sensor chip includes a detection coil arranged with the X-direction as its axial direction, a detection terminal used to detect an induced voltage generated by the detection coil, a test coil disposed at a position spaced apart from the detection coil, and a test terminal used to supply a test current to the test coil. The test coil is disposed at a position where an induced voltage is generated in the detection coil when the test current flows through the test coil.

### CROSS REFERENCE TO RELATED APPLICATION

This application is based upon and claims the benefit of priority of the prior Japanese Patent Application No. 2024-093936, filed on Jun. 10, 2024, the entire contents of which are incorporated herein by reference.

### TECHNICAL FIELD

The present disclosure relates to a magnetic sensor chip and a magnetic sensor module.

### BACKGROUND ART

Japanese Patent Application Laid-Open No. 2017-120204 discloses a magnetic sensor module including a Hall element, a conductive support member that supports the Hall element, and an encapsulating resin that covers the Hall element.

### PRIOR ART DOCUMENTS

### Patent Documents

Patent Document 1: Japanese Patent Application Laid-Open No. 2017-120204

### BRIEF DESCRIPTION OF THE DRAWINGS

FIG. 1 is a schematic perspective view illustrating an exemplary magnetic sensor chip according to a first embodiment.

FIG. 2 is a schematic plan view illustrating the magnetic sensor chip of FIG. 1.

FIG. 3 is a schematic sectional view illustrating the structure of the magnetic sensor chip taken along line F3-F3 of FIG. 2.

FIG. 4 is a schematic sectional view illustrating the structure of the magnetic sensor chip taken along line F4-F4 of FIG. 2.

FIG. 5 is a schematic enlarged plan view illustrating the first coil portion of the detection coil and its surroundings.

FIG. 6 is a schematic enlarged plan view illustrating the second coil portion of the detection coil and its surroundings.

FIG. 7 is a schematic enlarged plan view illustrating the test coil and its surroundings.

FIG. 8 is a schematic sectional view illustrating the structure of the magnetic sensor chip taken along line F8-F8 of FIG. 2.

FIG. 9 is a schematic plan view illustrating the internal structure of a magnetic sensor module including the magnetic sensor chip.

FIG. 10 is a schematic sectional view illustrating the structure of the magnetic sensor module taken along line F10-F10 of FIG. 9.

FIG. 11 is a schematic plan view illustrating an exemplary magnetic sensor chip according to a second embodiment.

FIG. 12 is a graph illustrating the relationship between the test current and the magnetic field strength.

FIG. 13 is a schematic plan view illustrating an exemplary magnetic sensor chip according to a third embodiment.

FIG. 14 is a schematic perspective view illustrating an exemplary magnetic sensor chip according to a fourth embodiment.

FIG. 15 is a schematic plan view illustrating the magnetic sensor chip of FIG. 14.

FIG. 16 is a schematic sectional view illustrating the structure of the magnetic sensor chip taken along line F16-F16 of FIG. 15.

FIG. 17 is a schematic sectional view illustrating the structure of the magnetic sensor chip taken along line F17-F17 of FIG. 15.

FIG. 18 is a schematic perspective view illustrating an exemplary magnetic sensor chip according to a fifth embodiment.

FIG. 19 is a schematic plan view illustrating the magnetic sensor chip of FIG. 18.

FIG. 20 is a schematic sectional view illustrating the structure of the magnetic sensor chip taken along line F20-F20 of FIG. 19.

FIG. 21 is a schematic sectional view illustrating the structure of the magnetic sensor chip taken along line F21-F21 of FIG. 19.

FIG. 22 is a schematic plan view illustrating an exemplary modified magnetic sensor chip.

FIG. 23 is a schematic sectional view illustrating the structure of the magnetic sensor chip taken along line F23-F23 of FIG. 22.

FIG. 24 is a schematic sectional view illustrating another modified example of the magnetic sensor chip.

FIG. 25 is a schematic sectional view illustrating a further modified example of the magnetic sensor chip.

FIG. 26 is a schematic plan view illustrating another modified example of the magnetic sensor chip.

FIG. 27 is a schematic sectional view illustrating a further modified example of the magnetic sensor chip.

### DETAILED DESCRIPTION

Below, several embodiments of the magnetic sensor chip and the magnetic sensor module of the present disclosure will be described with reference to the accompanying drawings. To simplify and clarify the description, components shown in the drawings are not necessarily drawn to scale. Additionally, in some sectional views, hatching lines may be omitted for ease of understanding. The attached drawings merely illustrate exemplary embodiments of the present disclosure and should not be construed as limiting the disclosure.

The following detailed description includes specific implementations of devices, systems, and methods embodying exemplary embodiments of the present disclosure. This detailed description is provided for explanatory purposes only and is not intended to limit the embodiments, applications, or uses of such embodiments.

The terms “first,” “second,” and “third,” etc., in the present disclosure are used merely as labels and do not necessarily indicate an order among the objects.

The term “at least one” as used in the present disclosure means “one or more.” For example, when there are two choices, “at least one” means “only one choice” or “both choices.” Likewise, when there are three or more choices, “at least one” means “only one choice” or “any combination of two or more choices.”

The term “dimension (width, length) of A is equal to the dimension (width, length) of B” or “the dimension (width, length) of A and the dimension (width, length) of B are equal to each other” as used in the present disclosure includes cases where the difference between the two dimensions is within 10% of the dimension of A.

### First Embodiment

### Overall Configuration of the Magnetic Sensor Chip

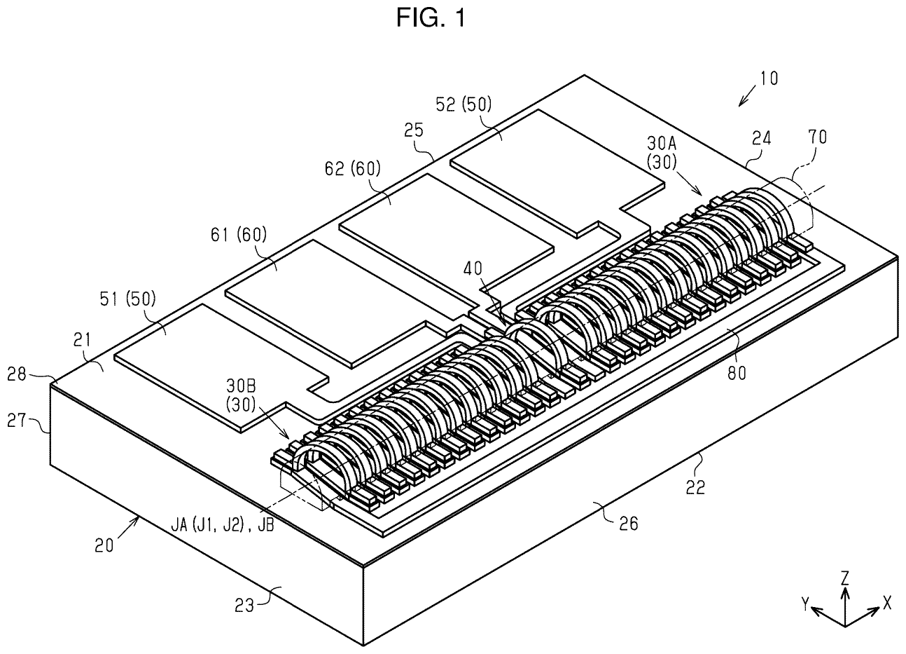

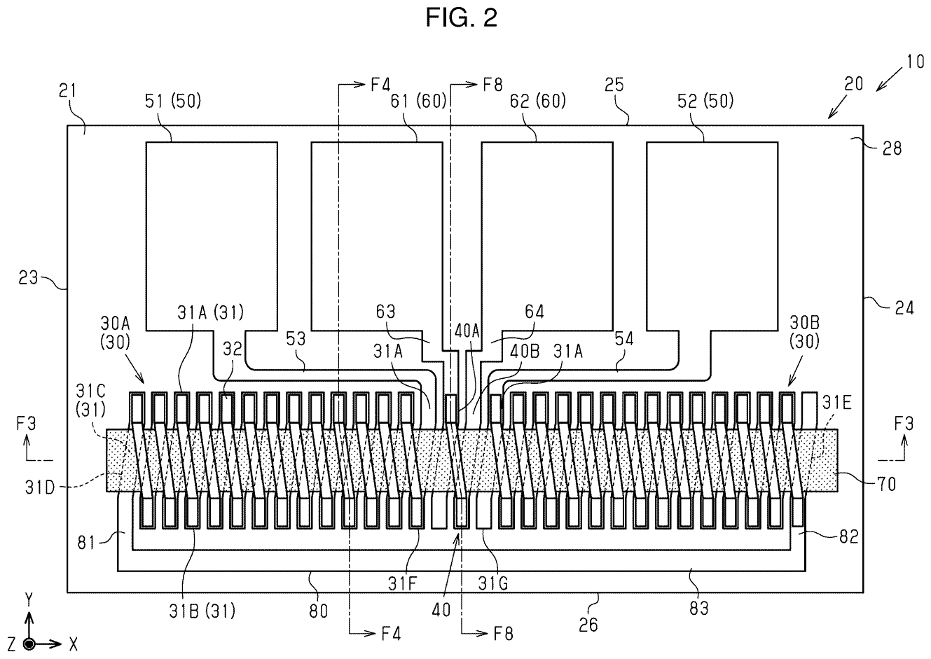

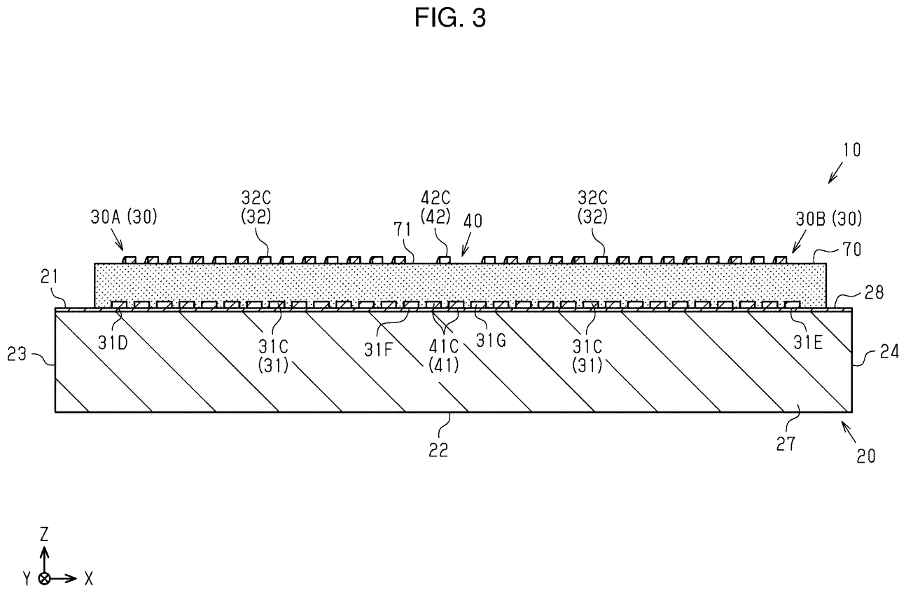

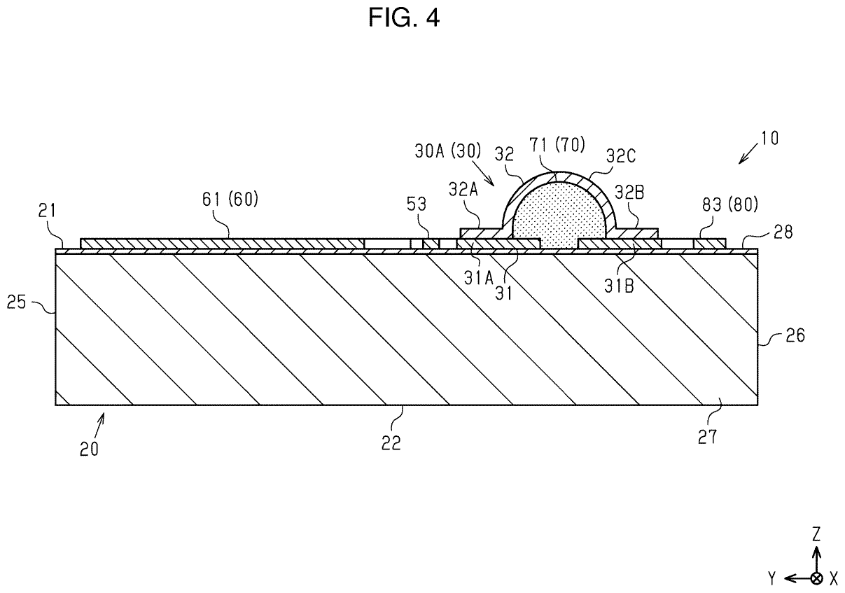

With reference to FIGS. 1 to 4, the overall configuration of the magnetic sensor chip 10 of the first embodiment will be described. FIG. 1 schematically illustrates the perspective structure of the magnetic sensor chip 10 of the first embodiment. FIG. 2 schematically illustrates the planar structure of the magnetic sensor chip 10 of FIG. 1. FIG. 3 schematically illustrates a sectional structure of the magnetic sensor chip 10 taken along line F3-F3 of FIG. 2. FIG. 4 schematically illustrates a sectional structure of the magnetic sensor chip 10 taken along line F4-F4 of FIG. 2.

As illustrated in FIGS. 1 and 2, the magnetic sensor chip 10 includes a substrate 20, a detection coil 30, a test coil 40, a detection terminal 50, a test terminal 60, and an insulating member 70.

The substrate 20 is a rectangular plate-like structure with a thickness direction along the Z-direction. In the following description, two directions orthogonal to the Z-direction will be referred to as the “X-direction” and “Y-direction.” The term “plan view” refers to viewing the magnetic sensor chip 10 from the Z-direction.

The substrate 20 is rectangular in shape, with the X-direction as the long side and the Y-direction as the short side in a plan view. The substrate 20 includes a substrate surface 21, a substrate back surface 22 opposite to the substrate surface 21, and four substrate side surfaces 23 to 26 connecting the substrate surface 21 and the substrate back surface 22.

The substrate 20 consists of a substrate body 27 and an insulating film 28. The substrate body 27 is made of, for example, a semiconductor material. The insulating film 28 is a coating film with electrical insulation properties. Alternatively, the substrate 20 may be formed of an insulating resin or ceramic.

The substrate body 27 is a substrate composed of a material containing silicon (Si). In one example, the substrate body 27 is a silicon (Si) substrate. The substrate body 27 may also be formed as a semiconductor substrate using a wide-bandgap semiconductor or a compound semiconductor. The wide-bandgap semiconductor may be silicon carbide (SiC). The compound semiconductor may be a III-V group compound semiconductor. The compound semiconductor may include at least one of aluminum nitride (AlN), indium nitride (InN), gallium nitride (GaN), and gallium arsenide (GaAs). Alternatively, instead of a semiconductor substrate, the substrate body 27 may be formed from an insulating substrate containing glass. Additionally, the substrate body 27 may be formed from a synthetic resin with epoxy resin or another main material.

The insulating film 28 is composed of, for example, silicon dioxide (SiO₂). This insulating film 28 is formed, for example, by thermally oxidizing a silicon substrate that serves as the substrate body 27. However, the material and formation method of the insulating film 28 are not limited to this example. In another example, the insulating film 28 may be composed of a material containing SiO₂ and resin. Furthermore, the insulating film 28 may be composed of silicon nitride (SiN), aluminum nitride (AlN), or other materials. The insulating film 28 may also be formed from a resin.

The insulating film 28 is provided on the surface of the substrate body 27. Therefore, the insulating film 28 forms the substrate surface 21. The back surface of the substrate body 27 forms the substrate back surface 22. The first to fourth substrate side surfaces 23 to 26 are formed by the side surfaces of the substrate body 27 and the insulating film 28.

The substrate surface 21, which is formed from the insulating film 28, is provided with the detection coil 30, the test coil 40, the detection terminal 50, the test terminal 60, and the insulating member 70. The detection coil 30 is used to detect magnetism in the magnetic sensor chip 10. The test coil 40 generates a magnetic field when a test current flows through it. The detection coil 30 detects the magnetism of the magnetic field generated by the test coil 40.

The detection coil 30, the test coil 40, and the insulating member 70 are arranged near the fourth substrate side surface 26 on the substrate surface 21 of the substrate 20. The test coil 40 is disposed at a position spaced apart from the detection coil 30. Specifically, the test coil 40 is arranged at a position where an induced voltage is generated in the detection coil 30 when a test current flows through the test coil 40. In one example, the test coil 40 is positioned in the X-direction relative to the detection coil 30. Here, the X-direction corresponds to the “first direction.”

The detection coil 30 is arranged with the X-direction as its axial direction. The detection coil 30 includes a first coil portion 30A and a second coil portion 30B, which are electrically connected to each other. The first coil portion 30A and the second coil portion 30B are positioned at the same location in the Y-direction but are spaced apart from each other in the X-direction. The first coil portion 30A is positioned closer to the first substrate side surface 23 than the second coil portion 30B in a plan view.

In the first embodiment, the test coil 40 is disposed between the first coil portion 30A and the second coil portion 30B in the X-direction. That is, the first coil portion 30A, the second coil portion 30B, and the test coil 40 are arranged in sequence along the X-direction. Both the first coil portion 30A and the second coil portion 30B are arranged with the X-direction as their axial direction. The axis J1 of the first coil portion 30A and the axis J2 of the second coil portion 30B are coaxial. In the first embodiment, the test coil 40 is also arranged with the X-direction as its axial direction. The axis JB of the test coil 40 is coaxial with the axis JA of the detection coil 30.

As shown in FIGS. 2 and 3, the insulating member 70 is provided so as to pass through the detection coil 30 and the test coil 40 in the X-direction. The insulating member 70 extends in a strip shape along the X-direction. As shown in FIG. 4, the insulating member 70 is in contact with the substrate surface 21 of the substrate 20. The insulating member 70 is formed to bulge away from the substrate surface 21 in the Z-direction. In one example, the cross-sectional shape of the insulating member 70 in a plane perpendicular to the X-direction (YZ plane) is an arc shape bulging away from the substrate surface 21. The insulating member 70 is composed of materials such as phenolic resin, polyimide resin, or epoxy resin.

The detection coil 30 and the test coil 40 are positioned to overlap with the insulating member 70 in a plan view. Parts of both the detection coil 30 and the test coil 40 are covered by the insulating member 70, while other parts are placed on top of the insulating member 70. In this manner, the detection coil 30 and the test coil 40 are arranged so as to surround the insulating member 70 when viewed from the X-direction.

The detection terminal 50 and the test terminal 60 are positioned near the third substrate side surface 25 on the substrate surface 21 of the substrate 20. As a result, both the detection terminal 50 and the test terminal 60 are spaced apart in the Y-direction from the test coil 40 and the detection coil 30. Here, the Y-direction corresponds to the “second direction.” The detection terminal 50 and the test terminal 60 are arranged at a distance from each other in the X-direction.

The detection terminal 50 is used to detect the induced voltage generated by the detection coil 30. The detection terminal 50 is electrically connected to the detection coil 30. The test terminal 60 is used to supply a test current to the test coil 40. The test terminal 60 is electrically connected to the test coil 40.

In the magnetic sensor chip 10 described above, when a test current flows to the test terminal 60, the test current flows through the test coil 40 via the test terminal 60. As a result, a magnetic field is generated in the test coil 40. This magnetic field induces a voltage in the detection coil 30. The induced voltage in the detection coil 30 is detected at the detection terminal 50.

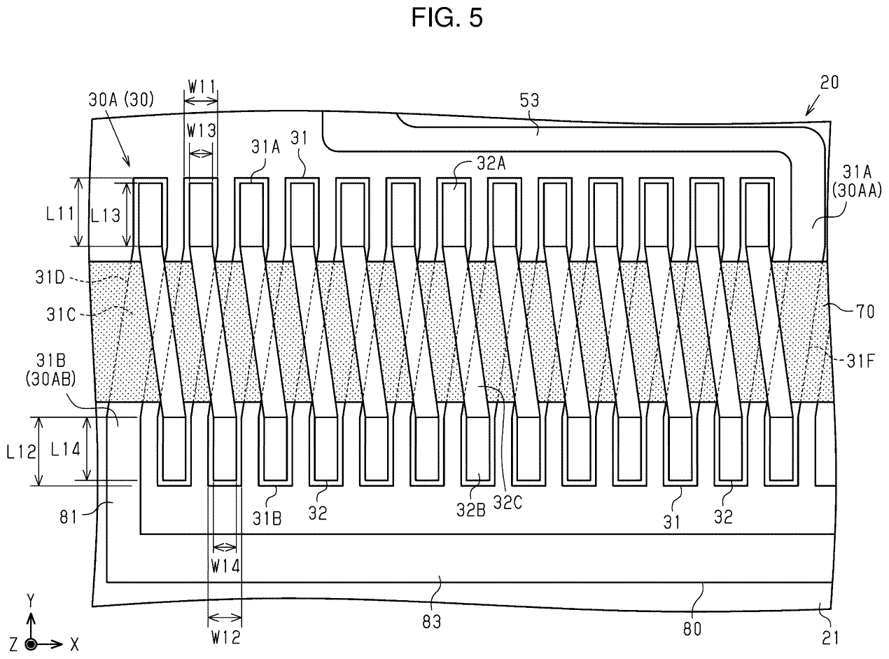

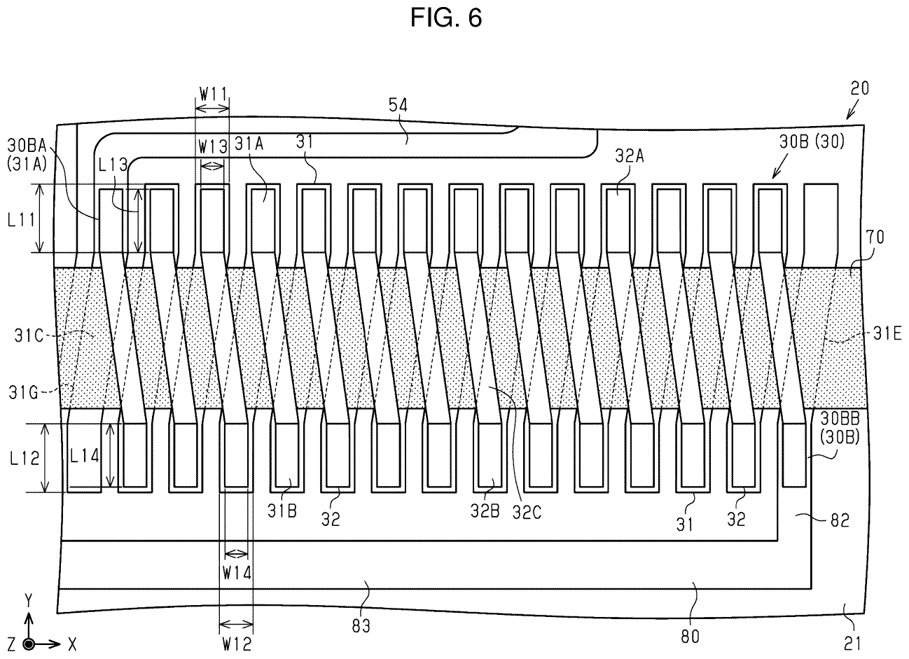

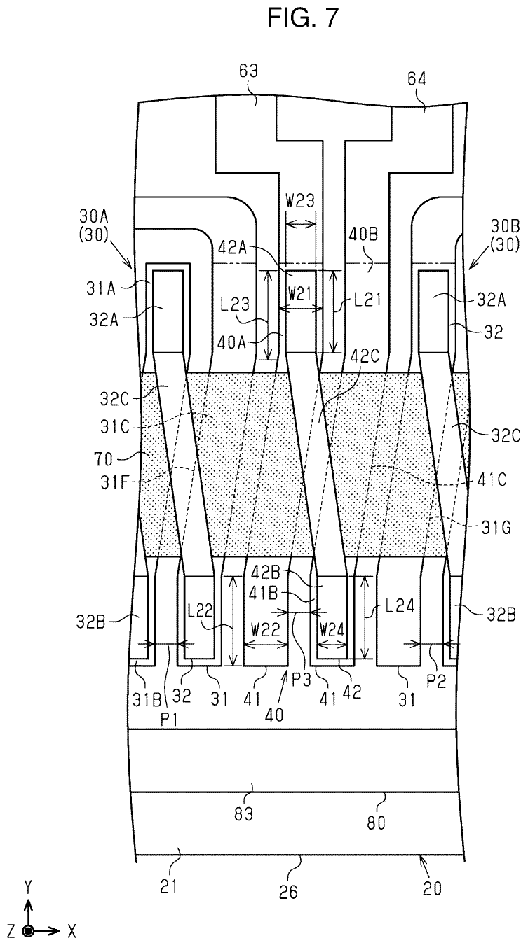

The following sections provide a detailed description of each component of the magnetic sensor chip 10 with reference to FIGS. 1 to 7. FIG. 5 schematically illustrates an enlarged plan structure of the first coil portion 30A of the detection coil 30 and its surroundings, as shown in FIG. 2. FIG. 6 schematically illustrates an enlarged plan structure of the second coil portion 30B of the detection coil 30 and its surroundings, as shown in FIG. 2. FIG. 7 schematically illustrates an enlarged plan structure of the test coil 40 and its surroundings, as shown in FIG. 2.

### Detection Coil

As shown in FIGS. 5 and 6, both the first coil portion 30A and the second coil portion 30B of the detection coil 30 include multiple first detection wirings 31 and multiple second detection wirings 32. Each first detection wiring 31 and each second detection wiring 32 is composed of a conductive metal such as copper (Cu), copper alloy, aluminum (Al), or aluminum alloy. In one example, the first detection wiring 31 and the second detection wiring 32 are composed of the same material. In the first embodiment, the number of turns in the first coil portion 30A and the number of turns in the second coil portion 30B are equal. The winding directions of the first coil portion 30A and the second coil portion 30B are the same.

The multiple first detection wirings 31 are provided on the substrate surface 21 of the substrate 20. The first detection wirings 31 are arranged apart from each other in the X-direction. In one example, the first detection wirings 31 are arranged at equal intervals in the X-direction. Each first detection wiring 31 extends along a direction intersecting the X-direction in a plan view. More specifically, each first detection wiring 31 extends in a direction intersecting both the X-direction and the Y-direction in the plane of the substrate surface 21. Most parts of each first detection wiring 31 are covered by the insulating member 70.

Each first detection wiring 31 includes a first end portion 31A, a second end portion 31B opposite the first end portion 31A, and a first conductor portion 31C that connects the first end portion 31A and the second end portion 31B. The first end portion 31A and the second end portion 31B both have a rectangular shape in a plan view, with the X-direction as the shorter side and the Y-direction as the longer side. Both the first end portion 31A and the second end portion 31B are exposed from the insulating member 70. The first end portion 31A is positioned closer to the detection terminal 50 (see FIG. 2) than the second end portion 31B.

The first end portions 31A of the multiple first detection wirings 31 are arranged offset from the second end portions 31B in the X-direction in a plan view. Each first end portion 31A is positioned between the second end portions 31B adjacent to it in the X-direction in a plan view.

Since the first conductor portion 31C connects the first end portion 31A and the second end portion 31B, it extends at a predetermined angle with respect to the Y-direction in a plan view. As shown in FIG. 2, the first conductor portion 31C of the first detection wiring 31 in the first coil portion 30A is inclined so that it approaches the test coil 40 as it extends from the second end portion 31B to the first end portion 31A in a plan view. Similarly, the first conductor portion 31C of the first detection wiring 31 in the second coil portion 30B is inclined so that it approaches the test coil 40 as it extends from the first end portion 31A to the second end portion 31B in a plan view. The inclination direction of the first conductor portion 31C in the first coil portion 30A and the second coil portion 30B is the same. In the first embodiment, the inclination angles of the first conductor portions 31C in the first coil portion 30A and the second coil portion 30B are equal. Here, the inclination angle of the first conductor portion 31C can be defined, for example, by the angle formed between the extending direction of the first conductor portion 31C and the Y-direction in a plan view. Each first conductor portion 31C is covered by the insulating member 70. As shown in FIG. 3, the insulating member 70 is in contact with the upper and side surfaces of each first conductor portion 31C.

As shown in FIGS. 5 and 6, the multiple second detection wirings 32 are arranged apart from each other in the X-direction. In one example, the second detection wirings 32 are arranged at equal intervals in the X-direction. Each second detection wiring 32 extends along a direction intersecting the X-direction in a plan view. More specifically, each second detection wiring 32 extends along a direction that intersects both the X-direction and the Y-direction in the plane perpendicular to the Z-direction in a plan view.

As shown in FIG. 4, each second detection wiring 32 is in contact with the insulating member 70. Each second detection wiring 32 is formed on top of the insulating member 70. More specifically, each second detection wiring 32 extends along the surface of the insulating member 70, which has an arc-shaped cross-section in a plane perpendicular to the X-direction (YZ plane). As a result, the central portion of each second detection wiring 32 is positioned away from the first detection wirings 31 in the Z-direction due to the insulating member 70. Each second detection wiring 32 is connected to two adjacent first detection wirings 31 in the X-direction. More specifically, each second detection wiring 32 connects the first end portion 31A of one first detection wiring 31 to the second end portion 31B of the adjacent first detection wiring 31 in the X-direction.

As shown in FIGS. 5 and 6, each second detection wiring 32 includes a third end portion 32A, a fourth end portion 32B opposite the third end portion 32A, and a second conductor portion 32C connecting the third end portion 32A and the fourth end portion 32B.

Both the third end portion 32A and the fourth end portion 32B have a rectangular shape in a plan view, with the X-direction as the shorter side and the Y-direction as the longer side. The third end portion 32A is positioned closer to the detection terminal 50 (see FIG. 2) than the fourth end portion 32B.

The third end portions 32A of the multiple second detection wirings 32 are arranged offset from the fourth end portions 32B in the X-direction in a plan view. Each third end portion 32A is positioned between the fourth end portions 32B adjacent to it in the X-direction in a plan view.

The third end portion 32A of the second detection wiring 32 is connected to the first end portion 31A of the first detection wiring 31. The fourth end portion 32B of the second detection wiring 32 is connected to the second end portion 31B of the adjacent first detection wiring 31. In other words, each second detection wiring 32 is connected between two adjacent first detection wirings 31 in the X-direction.

The second conductor portion 32C connects the third end portion 32A and the fourth end portion 32B. Therefore, the second conductor portion 32C extends at a predetermined angle with respect to the Y-direction in a plan view. As shown in FIG. 5, the second conductor portion 32C of the second detection wiring 32 in the first coil portion 30A is inclined away from the test coil 40 as it extends from the fourth end portion 32B to the third end portion 32A in a plan view. As shown in FIG. 6, the second conductor portion 32C of the second detection wiring 32 in the second coil portion 30B is inclined toward the test coil 40 as it extends from the fourth end portion 32B to the third end portion 32A in a plan view. As shown in FIGS. 5 and 6, the inclination direction of the second conductor portion 32C in the first coil portion 30A and the second coil portion 30B is the same. In the first embodiment, the inclination angles of the second conductor portions 32C in the first coil portion 30A and the second coil portion 30B are equal. Here, the inclination angle of the second conductor portion 32C can be defined, for example, by the angle between the extending direction of the second conductor portion 32C and the Y-direction in a plan view. In the first embodiment, the inclination angles of the second conductor portions 32C in the first coil portion 30A and the second coil portion 30B are equal to the inclination angles of the first conductor portions 31C in the first coil portion 30A and the second coil portion 30B.

The width of the second detection wiring 32 is narrower than that of the first detection wiring 31. Here, the width of the first detection wiring 31 is defined by the dimension in the direction perpendicular to the extending direction of the first detection wiring 31 in a plan view. The width of the second detection wiring 32 is defined by the dimension in the direction perpendicular to the extending direction of the second detection wiring 32 in a plan view.

The width W13 of the third end portion 32A of the second detection wiring 32 is narrower than the width W11 of the first end portion 31A of the first detection wiring 31. The length L13 of the third end portion 32A is shorter than the length L11 of the first end portion 31A. Similarly, the width W14 of the fourth end portion 32B of the second detection wiring 32 is narrower than the width W12 of the second end portion 31B of the first detection wiring 31. The length L14 of the fourth end portion 32B is shorter than the length L12 of the second end portion 31B.

In one example, the width W11 of the first end portion 31A is equal to the width W12 of the second end portion 31B. In one example, the length L11 of the first end portion 31A is equal to the length L12 of the second end portion 31B. In one example, the width W13 of the third end portion 32A is equal to the width W14 of the fourth end portion 32B. In one example, the length L13 of the third end portion 32A is equal to the length L14 of the fourth end portion 32B. In one example, the width of the first conductor portion 31C is equal to the widths W11 and W12 of the first and second end portions 31A and 31B. In one example, the width of the second conductor portion 32C is equal to the widths W13 and W14 of the third and fourth end portions 32A and 32B.

The width of the first conductor portion 31C can be adjusted as needed. In one example, the width of the first conductor portion 31C may be different from the widths W11 and W12 of the first and second end portions 31A and 31B. The width of the second conductor portion 32C can also be adjusted as needed. In one example, the width of the second conductor portion 32C may be different from the widths W13 and W14 of the third and fourth end portions 32A and 32B.

As shown in FIG. 2, the magnetic sensor chip 10 includes a coil connection wiring 80 provided on the substrate surface 21 of the substrate 20. The coil connection wiring 80 is provided on the insulating film 28. The coil connection wiring 80 is made of a conductive metal such as Cu, Cu alloy, Al, or Al alloy. In one example, the coil connection wiring 80 is made of the same material as the first detection wiring 31 and the second detection wiring 32.

The coil connection wiring 80 electrically connects the first coil portion 30A and the second coil portion 30B. The coil connection wiring 80 is connected to the first detection wiring 31 in the first coil portion 30A and the first detection wiring 31 in the second coil portion 30B. The coil connection wiring 80 connects the end portion of the first coil portion 30A on the side opposite the test coil 40 in the X-direction to the end portion of the second coil portion 30B on the side opposite the test coil 40 in the X-direction. More specifically, the coil connection wiring 80 is connected to the first detection wiring 31D at the end portion opposite the test coil 40 among the multiple first detection wirings 31 arranged in the X-direction in the first coil portion 30A. The coil connection wiring 80 is also connected to the first detection wiring 31E at the end portion opposite the test coil 40 among the multiple first detection wirings 31 arranged in the X-direction in the second coil portion 30B. The coil connection wiring 80 is connected to the second end portion 31B of the first detection wiring 31D. The coil connection wiring 80 is also connected to the second end portion 31B of the first detection wiring 31E. In one example, the coil connection wiring 80 is integrated with the first detection wirings 31D and 31E.

The coil connection wiring 80 is positioned in the Y-direction on the side opposite the test terminal 60 and the detection terminal 50 relative to the test coil 40 and the detection coil 30. The coil connection wiring 80 includes a first connection portion 81, a second connection portion 82, and a third connection portion 83.

The first connection portion 81 is the part that connects to the first detection wiring 31D. The first connection portion 81 extends in the Y-direction from the second end portion 31B of the first detection wiring 31D toward the fourth substrate side surface 26 in a plan view. In one example, the width of the first connection portion 81 is equal to the width W12 of the second end portion 31B of the first detection wiring 31. Here, the width of the first connection portion 81 is defined by the dimension in the direction perpendicular to its extending direction in a plan view.

The second connection portion 82 is the part that connects to the first detection wiring 31E. The second connection portion 82 extends in the Y-direction from the second end portion 31B of the first detection wiring 31E toward the fourth substrate side surface 26 in a plan view. In one example, the length of the second connection portion 82 in the Y-direction is equal to the length of the first connection portion 81 in the Y-direction. In one example, the width of the second connection portion 82 is equal to the width W12 of the second end portion 31B of the first detection wiring 31. Therefore, the width of the second connection portion 82 is equal to the width of the first connection portion 81. Here, the width of the second connection portion 82 is defined by the dimension in the direction perpendicular to its extending direction in a plan view. Similarly, the width of the third connection portion 83 is defined by the dimension perpendicular to its extending direction in a plan view.

The third connection portion 83 is the part that connects the first connection portion 81 and the second connection portion 82. The third connection portion 83 is positioned in the Y-direction near the fourth substrate side surface 26, spaced apart from the detection coil 30 and the test coil 40. The third connection portion 83 extends in the X-direction. In one example, the width of the third connection portion 83 is larger than the widths of the first connection portion 81 and the second connection portion 82.

The widths of the first to third connection portions 81 to 83 can be arbitrarily adjusted. In one example, the width of the first connection portion 81 may be larger than the width W12 of the second end portion 31B of the first detection wiring 31. In one example, the width of the second connection portion 82 may be larger than the width W12 of the second end portion 31B of the first detection wiring 31. In one example, the width of the third connection portion 83 may be equal to the width of the first connection portion 81. In one example, the width of the third connection portion 83 may be equal to the width of the second connection portion 82.

The first coil portion 30A includes a first end portion 30AA and a second end portion 30AB. The first end portion 30AA is the end portion of the first coil portion 30A on the test coil 40 side in the X-direction. The second end portion 30AB is the end portion of the first coil portion 30A on the side opposite the test coil 40 in the X-direction. The first end portion 30AA is formed by the first end portion 31A of the first detection wiring 31F, which is located on the test coil 40 side among the multiple first detection wirings 31 in the first coil portion 30A. The second end portion 30AB is formed by the second end portion 31B of the first detection wiring 31D, which is located on the side opposite the test coil 40 among the multiple first detection wirings 31 in the first coil portion 30A. Therefore, the first connection portion 81 of the coil connection wiring 80 is connected to the second end portion 30AB of the first coil portion 30A. The first connection portion 81 extends from the second end portion 31B of the first detection wiring 31D toward the fourth substrate side surface 26 (see FIG. 2). As a result, the first connection portion 81 is positioned closer to the fourth substrate side surface 26 than the second end portion 31B of the first detection wiring 31.

The second coil portion 30B includes a first end portion 30BA and a second end portion 30BB. The first end portion 30BA is the end portion of the second coil portion 30B on the test coil 40 side in the X-direction. The second end portion 30BB is the end portion of the second coil portion 30B on the side opposite the test coil 40 in the X-direction. The first end portion 30BA is formed by the first end portion 31A of the first detection wiring 31G, which is located on the test coil 40 side among the multiple first detection wirings 31 in the second coil portion 30B. The second end portion 30BB is formed by the first end portion 31A of the first detection wiring 31E, which is located on the side opposite the test coil 40 among the multiple first detection wirings 31 in the second coil portion 30B. Therefore, the second connection portion 82 of the coil connection wiring 80 is connected to the second end portion 30BB of the second coil portion 30B.

### Test Coil

As shown in FIG. 7, in the first embodiment, the number of turns of the test coil 40 is one. That is, the number of turns of the test coil 40 is fewer than that of the detection coil 30. The number of turns of the test coil 40 is also fewer than the number of turns of the first coil portion 30A and the second coil portion 30B.

The test coil 40 includes a first end portion 40A and a second end portion 40B. The first end portion 40A is the end portion of the test coil 40 on the first coil portion 30A side in the X-direction. The second end portion 40B is the end portion of the test coil 40 on the second coil portion 30B side in the X-direction. The first end portion 40A is spaced apart from the first coil portion 30A in the X-direction. The second end portion 40B is spaced apart from the second coil portion 30B in the X-direction.

The test coil 40 includes two first test wirings 41 and one second test wiring 42. The first test wirings 41 and the second test wiring 42 are composed of a conductive metal such as Cu, Cu alloy, Al, or Al alloy. In one example, the first test wirings 41 and the second test wiring 42 are made of the same material. In one example, the first test wirings 41 and the second test wiring 42 are made of the same material as the first detection wirings 31 and the second detection wirings 32.

The two first test wirings 41 are provided on the substrate surface 21 of the substrate 20. The two first test wirings 41 are spaced apart from each other in the X-direction. The two first test wirings 41 are arranged to extend in a direction intersecting the X-direction in a plan view. The two first test wirings 41 extend parallel to each other in a plan view. Each first test wiring 41 extends parallel to the first detection wiring 31 in a plan view.

The two first test wirings 41 extend in a direction intersecting the X-direction in a plan view. More specifically, each first test wiring 41 extends in a direction intersecting both the X-direction and the Y-direction in the plane of the substrate surface 21 in a plan view. In one example, the spacing P3 between the two first test wirings 41 is equal to the spacing P1 between the multiple first detection wirings 31 in the first coil portion 30A and the spacing P2 between the multiple first detection wirings 31 in the second coil portion 30B. Most parts of each first test wiring 41 are covered by the insulating member 70.

Each first test wiring 41 includes a first end portion 41A, a second end portion 41B opposite the first end portion 41A, and a first conductor portion 41C between the first end portion 41A and the second end portion 41B. Among the two first test wirings 41, the first end portion 41A of the first test wiring 41 located closer to the first coil portion 30A forms the first end portion 40A of the test coil 40. The first end portion 41A of the first test wiring 41 located closer to the second coil portion 30B forms the second end portion 40B of the test coil 40.

Both the first end portion 41A and the second end portion 41B have a rectangular shape in a plan view, with the X-direction as the shorter side and the Y-direction as the longer side. Both the first end portion 41A and the second end portion 41B are exposed from the insulating member 70. The first end portion 41A is positioned closer to the test terminal 60 (see FIG. 2) than the second end portion 41B.

The first end portions 41A of the two first test wirings 41 are arranged offset from the second end portions 41B in the X-direction in a plan view. Each first end portion 41A is positioned between the second end portions 41B adjacent to it in the X-direction in a plan view.

Since the first conductor portion 41C connects the first end portion 41A and the second end portion 41B, it extends at a predetermined angle with respect to the Y-direction in a plan view. The first conductor portion 41C of the first test wiring 41 is inclined in a plan view such that it approaches the first coil portion 30A of the detection coil 30 as it extends from the second end portion 41B to the first end portion 41A. The inclination direction of the first conductor portion 41C in the first test wiring 41, the first conductor portion 31C in the first coil portion 30A, and the first conductor portion 31C in the second coil portion 30B are the same. In the first embodiment, the inclination angles of the first conductor portion 41C in the first test wiring 41, the first conductor portion 31C in the first coil portion 30A, and the first conductor portion 31C in the second coil portion 30B are equal. Here, the inclination angle of the first conductor portion 41C can be defined, for example, by the angle between the extending direction of the first conductor portion 41C and the Y-direction in a plan view. As shown in FIG. 3, the insulating member 70 is in contact with the upper and side surfaces of each first conductor portion 41C.

The second test wiring 42 extends in a direction intersecting the X-direction in a plan view. More specifically, the second test wiring 42 extends along a direction that intersects both the X-direction and the Y-direction in the plane perpendicular to the Z-direction in a plan view. The second test wiring 42 extends parallel to the second detection wiring 32 in a plan view.

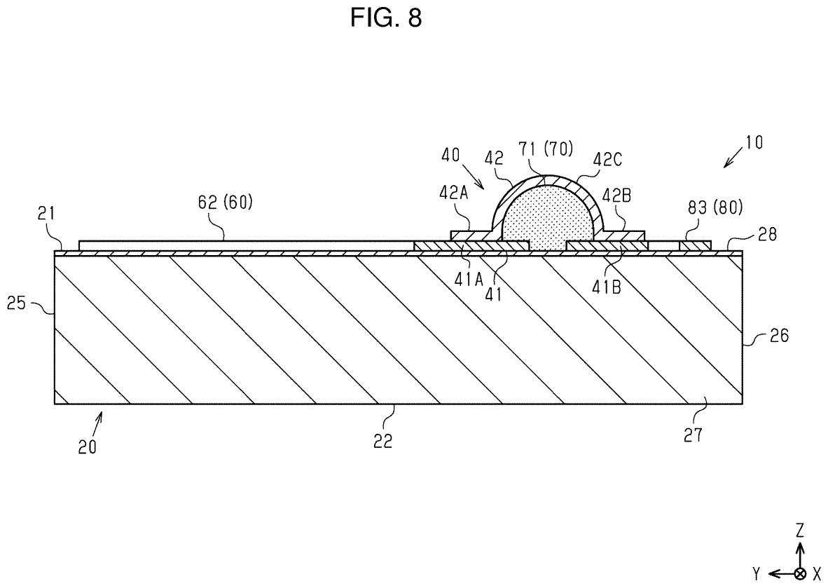

As shown in FIG. 8, the second test wiring 42 is in contact with the insulating member 70. Each second test wiring 42 is formed on the insulating member 70. More specifically, each second test wiring 42 extends along the surface of the insulating member 70, which has an arc-shaped cross-section in a plane perpendicular to the X-direction (YZ plane). As a result, the central portion of each second test wiring 42 is positioned away from the first test wirings 41 in the Z-direction due to the insulating member 70. Each second test wiring 42 is connected to two first test wirings 41. More specifically, each second test wiring 42 connects the first end portion 41A of one first test wiring 41 to the second end portion 41B of the other first test wiring 41.

As shown in FIG. 7, the second test wiring 42 includes a third end portion 42A, a fourth end portion 42B opposite the third end portion 42A, and a second conductor portion 42C between the third end portion 42A and the fourth end portion 42B.

Both the third end portion 42A and the fourth end portion 42B have a rectangular shape in a plan view, with the X-direction as the shorter side and the Y-direction as the longer side. The third end portion 42A is positioned closer to the test terminal 60 (see FIG. 2) than the fourth end portion 42B. The third end portion 42A is arranged offset from the fourth end portion 42B in the X-direction in a plan view.

The third end portion 42A of the second test wiring 42 is connected to the first end portion 41A of the first test wiring 41. The fourth end portion 42B of the second test wiring 42 is connected to the second end portion 41B of the adjacent first test wiring 41 to which the third end portion 42A is connected.

The second conductor portion 42C connects the third end portion 42A and the fourth end portion 42B. Therefore, the second conductor portion 42C extends at a predetermined angle with respect to the Y-direction in a plan view. The second conductor portion 42C is inclined in a plan view such that it approaches the first coil portion 30A as it extends from the fourth end portion 42B to the third end portion 42A. The inclination direction of the second conductor portion 42C, the second conductor portion 32C of the first coil portion 30A, and the second conductor portion 32C of the second coil portion 30B are the same. In the first embodiment, the inclination angles of the second conductor portion 42C, the second conductor portion 32C of the first coil portion 30A, and the second conductor portion 32C of the second coil portion 30B are equal. Here, the inclination angle of the second conductor portion 42C can be defined by the angle formed between its extending direction and the Y-direction in a plan view. In the first embodiment, the inclination angle of the second conductor portion 42C is equal to the inclination angle of the first conductor portion 41C.

The width of the second test wiring 42 is narrower than that of the first test wiring 41. Here, the width of the first test wiring 41 is defined by the dimension in the direction perpendicular to its extending direction in a plan view. The width of the second test wiring 42 is defined by the dimension in the direction perpendicular to its extending direction in a plan view.

The width W23 of the third end portion 42A of the second test wiring 42 is narrower than the width W21 of the first end portion 41A of the first test wiring 41. The length L23 of the third end portion 42A is shorter than the length L21 of the first end portion 41A. Similarly, the width W24 of the fourth end portion 42B of the second test wiring 42 is narrower than the width W22 of the second end portion 41B of the first test wiring 41. The length L24 of the fourth end portion 42B is shorter than the length L22 of the second end portion 41B.

In one example, the width W21 of the first end portion 41A is equal to the width W22 of the second end portion 41B. In one example, the length L21 of the first end portion 41A is equal to the length L22 of the second end portion 41B. In one example, the width W23 of the third end portion 42A is equal to the width W24 of the fourth end portion 42B. In one example, the length L23 of the third end portion 42A is equal to the length L24 of the fourth end portion 42B. In one example, the width of the first conductor portion 41C is equal to the widths W21 and W22 of the first and second end portions 41A and 41B. In one example, the width of the second conductor portion 42C is equal to the widths W23 and W24 of the third and fourth end portions 42A and 42B.

In one example, the width of the first test wiring 41 is equal to the width of the first detection wiring 31. In one example, the width W21 of the first end portion 41A of the first test wiring 41 is equal to the width W11 of the first end portion 31A of the first detection wiring 31. In one example, the width W22 of the second end portion 41B of the first test wiring 41 is equal to the width W12 of the second end portion 31B of the first detection wiring 31. In one example, the width W23 of the third end portion 42A of the second test wiring 42 is equal to the width W13 of the third end portion 32A of the second detection wiring 32. In one example, the width W24 of the fourth end portion 42B of the second test wiring 42 is equal to the width W14 of the fourth end portion 32B of the second detection wiring 32. In one example, the width of the first conductor portion 41C of the first test wiring 41 is equal to the width of the first conductor portion 31C of the first detection wiring 31. In one example, the width of the second conductor portion 42C of the second test wiring 42 is equal to the width of the second conductor portion 32C of the second detection wiring 32.

The width of the first conductor portion 41C can be adjusted as needed. In one example, the width of the first conductor portion 41C may be different from the widths W21 and W22 of the first end portion 41A and the second end portion 41B. The width of the second conductor portion 42C can also be adjusted as needed. In one example, the width of the second conductor portion 42C may be different from the widths W23 and W24 of the third end portion 42A and the fourth end portion 42B.

### Detection Terminals and Test Terminals

As shown in FIG. 2, the detection terminal 50 includes a first detection terminal 51 and a second detection terminal 52, which are spaced apart in the X-direction. The first detection terminal 51 is positioned closer to the first substrate side surface 23 than the center of the substrate 20 in the X-direction in a plan view. The first detection terminal 51 is located adjacent to the first coil portion 30A in the Y-direction. The second detection terminal 52 is positioned closer to the second substrate side surface 24 than the center of the substrate 20 in the X-direction in a plan view. The second detection terminal 52 is located adjacent to the second coil portion 30B in the Y-direction. Both the first detection terminal 51 and the second detection terminal 52 have a rectangular shape in a plan view. In one example, both the first detection terminal 51 and the second detection terminal 52 have a rectangular shape with the X-direction as the shorter side and the Y-direction as the longer side in a plan view. In one example, the size and shape of the first detection terminal 51 and the second detection terminal 52 are identical.

As shown in FIGS. 2 and 5, the first detection terminal 51 is electrically connected to the first coil portion 30A. More specifically, the first detection terminal 51 is connected to the first coil portion 30A via the first connection wiring 53. The first connection wiring 53 is connected to the first end portion 31A of the first detection wiring 31F, which is located at the test coil 40 side among the multiple first detection wirings 31 in the first coil portion 30A. The first connection wiring 53 is integrated with the first end portion 31A of the first detection wiring 31F.

As shown in FIGS. 2 and 6, the second detection terminal 52 is electrically connected to the second coil portion 30B. More specifically, the second detection terminal 52 is connected to the second coil portion 30B via the second connection wiring 54. The second connection wiring 54 is connected to the first end portion 31A of the first detection wiring 31G, which is located at the test coil 40 side among the multiple first detection wirings 31 in the second coil portion 30B. The second connection wiring 54 is integrated with the first end portion 31A of the first detection wiring 31G.

As shown in FIGS. 5 and 6, both the first connection wiring 53 and the second connection wiring 54 are provided on the substrate surface 21 of the substrate 20. The first connection wiring 53 and the second connection wiring 54 are composed of a conductive metal such as Cu, Cu alloy, Al, or Al alloy. In one example, the first connection wiring 53 and the second connection wiring 54 are made of the same material. In one example, the first connection wiring 53 and the second connection wiring 54 are made of the same material as the first detection wiring 31 and the second detection wiring 32.

As shown in FIG. 2, the test terminal 60 includes a first test terminal 61 and a second test terminal 62, which are arranged side by side in the X-direction. Both the first test terminal 61 and the second test terminal 62 are positioned between the first detection terminal 51 and the second detection terminal 52 in the X-direction. The first test terminal 61 is positioned between the first detection terminal 51 and the second test terminal 62 in the X-direction. The second test terminal 62 is positioned between the first test terminal 61 and the second detection terminal 52 in the X-direction. Both the first test terminal 61 and the second test terminal 62 have a rectangular shape in a plan view. In one example, both the first test terminal 61 and the second test terminal 62 have a rectangular shape with the X-direction as the shorter side and the Y-direction as the longer side in a plan view. In one example, the size and shape of the first test terminal 61 and the second test terminal 62 are identical. In one example, the size and shape of the first test terminal 61 and the second test terminal 62 are the same as those of the first detection terminal 51 and the second detection terminal 52.

As shown in FIGS. 2 and 7, the first test terminal 61 is electrically connected to the first end portion 40A of the test coil 40. More specifically, the first test terminal 61 is connected to the first end portion 40A of the test coil 40 via the third connection wiring 63. The third connection wiring 63 is integrated with the first end portion 41A of the first test wiring 41 located closer to the first coil portion 30A among the two first test wirings 41.

The second test terminal 62 is electrically connected to the second end portion 40B of the test coil 40. More specifically, the second test terminal 62 is connected to the second end portion 40B of the test coil 40 via the fourth connection wiring 64. The fourth connection wiring 64 is integrated with the first end portion 41A of the first test wiring 41 located closer to the second coil portion 30B among the two first test wirings 41.

Both the third connection wiring 63 and the fourth connection wiring 64 are provided on the substrate surface 21 of the substrate 20. The third connection wiring 63 and the fourth connection wiring 64 are positioned in the X-direction between the first connection wiring 53 and the second connection wiring 54. The third connection wiring 63 and the fourth connection wiring 64 are composed of a conductive metal such as Cu, Cu alloy, Al, or Al alloy. In one example, the third connection wiring 63 and the fourth connection wiring 64 are made of the same material. In one example, the third connection wiring 63 and the fourth connection wiring 64 are made of the same material as the first connection wiring 53 and the second connection wiring 54.

In one example, the multiple first detection wirings 31 of the detection coil 30, the multiple first test wirings 41 of the test coil 40, the first connection wiring 53, the second connection wiring 54, the third connection wiring 63, the fourth connection wiring 64, and the coil connection wiring 80 are formed on the substrate surface 21 of the substrate 20 using a plating method. More specifically, after forming a mask with openings corresponding to the multiple first detection wirings 31, the multiple first test wirings 41, the first connection wiring 53, the second connection wiring 54, the third connection wiring 63, the fourth connection wiring 64, and the coil connection wiring 80 on the substrate surface 21, plating metal is deposited in the mask openings to form these structures. The mask is formed by exposing and developing a resist layer with photosensitivity.

Additionally, the multiple second detection wirings 32 of the detection coil 30 and the multiple second test wirings 42 of the test coil 40 are formed using a plating method on the insulating member 70, the first detection wirings 31, and the first test wirings 41. More specifically, after forming a mask with openings corresponding to the multiple second detection wirings 32 and the multiple second test wirings 42 on the insulating member 70, the first end portions 31A and the second end portions 31B of the first detection wirings 31, and the first end portions 41A and the second end portions 41B of the first test wirings 41, plating metal is deposited in the mask openings to form these structures. The mask is formed by exposing and developing a resist layer with photosensitivity.

The detection terminal 50 and the test terminal 60 may also be formed using a plating method. In this case, the detection terminal 50 and the test terminal 60 may be formed in the same process as the multiple first detection wirings 31, the multiple first test wirings 41, the first connection wiring 53, the second connection wiring 54, the third connection wiring 63, the fourth connection wiring 64, and the coil connection wiring 80.

### Magnetic Sensor Module

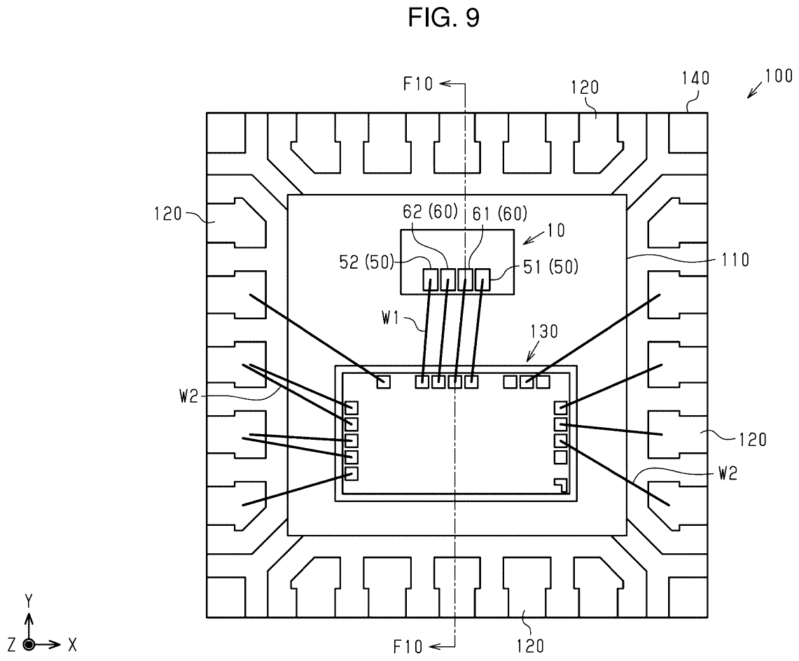

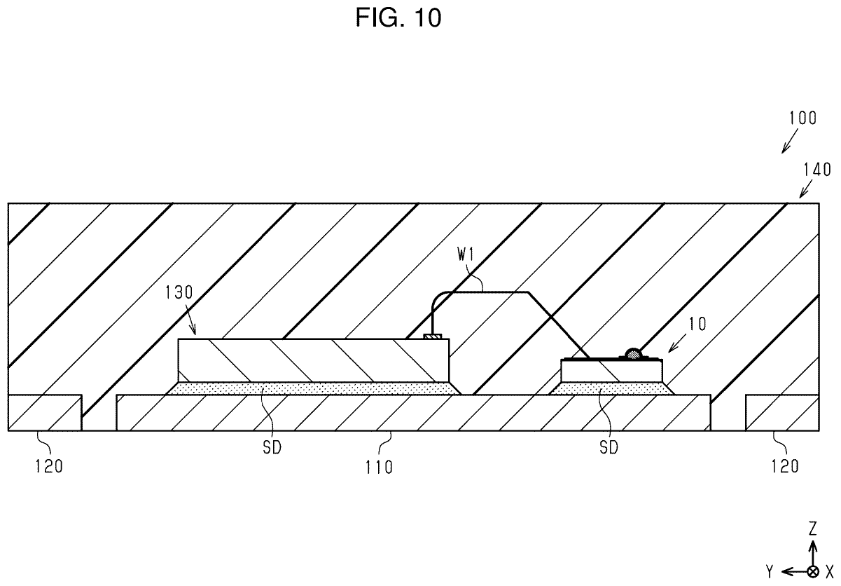

Next, with reference to FIGS. 9 and 10, the configuration of the magnetic sensor module 100 including the magnetic sensor chip 10 will be described. FIG. 9 schematically illustrates the internal structure of the magnetic sensor module 100. FIG. 10 schematically illustrates the sectional structure of the magnetic sensor module 100 taken along line F10-F10 of FIG. 9. Note that in FIG. 9, the configuration of the magnetic sensor chip 10 is simplified for clarity.

As shown in FIGS. 9 and 10, the magnetic sensor module 100 includes a die pad 110, external terminals 120, a control chip 130, and an encapsulating resin 140.

The die pad 110 is a flat plate with the Z-direction as the thickness direction. The die pad 110 is composed of a conductive material such as Cu, Cu alloy, Al, or Al alloy. The magnetic sensor chip 10 and the control chip 130 are mounted on the die pad 110. The magnetic sensor chip 10 and the control chip 130 are arranged apart from each other in the Y-direction on the die pad 110. Both the magnetic sensor chip 10 and the control chip 130 are bonded to the die pad 110 using a conductive bonding material SD.

The magnetic sensor chip 10 and the control chip 130 are electrically connected by multiple wires W1 (four in the first embodiment). The multiple wires W1 are individually connected to the detection terminals 50 and test terminals 60 of the magnetic sensor chip 10. Specifically, the multiple wires W1 are individually connected to the first detection terminal 51, the second detection terminal 52, the first test terminal 61, and the second test terminal 62. This allows the control chip 130 to be electrically connected to the detection terminals 50 and test terminals 60 of the magnetic sensor chip 10 separately.

The control chip 130 is configured to supply a test current to the test terminals 60 and to detect the induced voltage generated in the detection coil 30 due to the test current flowing through the test coil 40 via the detection terminals 50. In one example, the control chip 130 includes a current source that supplies a test current to the test terminals 60 and an acquisition unit that obtains the induced voltage of the detection coil 30. The acquisition unit is electrically connected to the first detection terminal 51 and the second detection terminal 52 and acquires the voltage between the first detection terminal 51 and the second detection terminal 52 as the induced voltage.

The external terminals 120 are arranged in multiple positions around the die pad 110 in a plan view. Some of the multiple external terminals 120 are electrically connected to the control chip 130 via multiple wires W2. The multiple external terminals 120 serve as connection terminals that are electrically connected to the wiring of a circuit board when the magnetic sensor module 100 is mounted on a circuit board (not shown).

The encapsulating resin 140 encapsulates at least the magnetic sensor chip 10 and the control chip 130. In one example, the encapsulating resin 140 encapsulates the magnetic sensor chip 10, the control chip 130, the multiple wires W1, and the multiple wires W2. The encapsulating resin 140 partially encapsulates the die pad 110 and the multiple external terminals 120. The back surface of the die pad 110 and the back surfaces of the external terminals 120 are exposed from the encapsulating resin 140. In one example, the side surfaces of the external terminals 120 are exposed from the side surfaces of the encapsulating resin 140.

### Operation of the First Embodiment

The operation of the first embodiment will now be described.

Generally, when performing an operation check to determine whether the detection coil of a magnetic sensor chip is functioning correctly, an external device such as a Helmholtz coil that generates a uniform magnetic field is required. In particular, an operation check of a magnetic sensor module that includes a magnetic sensor chip requires a larger external device.

In this regard, in the first embodiment of the magnetic sensor chip 10, the test coil 40 generates a magnetic field that induces a voltage in the detection coil 30 by supplying a test current to the test coil 40. This allows the operation check of the detection coil 30 to be performed without using an external device that generates a uniform magnetic field. Additionally, based on the relationship between the test current of the test coil 40 and the induced voltage of the detection coil 30, the sensitivity of the magnetic sensor chip 10 can be calibrated.

### Effects of the First Embodiment

According to the magnetic sensor chip 10 and the magnetic sensor module 100 of the first embodiment, the following effects can be obtained.
(1-1) The magnetic sensor chip 10 includes a detection coil 30 arranged with the X-direction as its axial direction, a detection terminal 50 used to detect an induced voltage generated by the detection coil 30, a test coil 40 disposed at a position spaced apart from the detection coil 30, and a test terminal 60 used to supply a test current to the test coil 40. The test coil 40 is positioned such that when a test current flows through the test coil 40, an induced voltage is generated in the detection coil 30.

With this configuration, the test coil 40 can be used to check the operation of the detection coil 30. Therefore, the operation check of the detection coil 30 can be easily performed without using an external device such as a Helmholtz coil that generates a uniform magnetic field.
(1-2) The test coil 40 is disposed at a position spaced apart in the X-direction from the detection coil 30. The test coil 40 is arranged with the X-direction as its axial direction.
   With this configuration, the magnetic field generated in the test coil 40 by the test current can more effectively influence the detection coil 30. Therefore, the magnetic field generated in the test coil 40 more easily induces a voltage in the detection coil 30.
(1-3) Both the test terminal 60 and the detection terminal 50 are disposed at positions spaced apart in the Y-direction from the test coil 40 and the detection coil 30. The test terminal 60 and the detection terminal 50 are also arranged apart from each other in the X-direction.

With this configuration, the arrangement direction of the test terminal 60 and the detection terminal 50 matches the arrangement direction of the test coil 40 and the detection coil 30. Furthermore, the test terminal 60 and the detection terminal 50 are positioned in a direction perpendicular to the arrangement direction of the test coil 40 and the detection coil 30. As a result, compared to a case where the test terminal 60 and the detection terminal 50 are dispersed on both sides of the test coil 40 and the detection coil 30 along their arrangement direction, the conductive path between the detection terminal 50 and the detection coil 30, as well as the conductive path between the test terminal 60 and the test coil 40, can be shortened.
(1-4) The detection coil 30 includes a first coil portion 30A and a second coil portion 30B, which are electrically connected to each other. The test coil 40, the first coil portion 30A, and the second coil portion 30B are arranged in sequence along the X-direction. The test coil 40 is disposed between the first coil portion 30A and the second coil portion 30B in the X-direction.

With this configuration, the test coil 40 can be positioned adjacent to both the first coil portion 30A and the second coil portion 30B. Therefore, the magnetic field generated in the test coil 40 can more easily induce a voltage in the detection coil 30.
(1-5) The detection terminal 50 includes a first detection terminal 51 electrically connected to the first coil portion 30A and a second detection terminal 52 electrically connected to the second coil portion 30B. The first detection terminal 51 and the second detection terminal 52 are spaced apart in the X-direction. The test terminal 60 includes a first test terminal 61 electrically connected to the first end portion 40A of the test coil 40 and a second test terminal 62 electrically connected to the second end portion 40B of the test coil 40. Both the first test terminal 61 and the second test terminal 62 are positioned in the X-direction between the first detection terminal 51 and the second detection terminal 52.

With this configuration, both the first test terminal 61 and the second test terminal 62 are placed near the test coil 40, which is located between the first coil portion 30A and the second coil portion 30B in the X-direction. Therefore, the conductive path between the first end portion 40A of the test coil 40 and the first test terminal 61, as well as the conductive path between the second end portion 40B of the test coil 40 and the second test terminal 62, can each be shortened.
(1-6) The magnetic sensor chip 10 includes a first connection wiring 53 connecting the first detection terminal 51 and the first coil portion 30A, and a second connection wiring 54 connecting the second detection terminal 52 and the second coil portion 30B. The first connection wiring 53 is connected to the end portion of the first coil portion 30A on the test coil 40 side. The second connection wiring 54 is connected to the end portion of the second coil portion 30B on the test coil 40 side.

With this configuration, the conductive path between the first detection terminal 51 and the first coil portion 30A, as well as the conductive path between the second detection terminal 52 and the second coil portion 30B, can each be shortened. Consequently, both the first connection wiring 53 and the second connection wiring 54 can be shortened.
(1-7) The magnetic sensor chip 10 includes a third connection wiring 63 connecting the first test terminal 61 and the first end portion 40A of the test coil 40 on the first coil portion 30A side, and a fourth connection wiring 64 connecting the second test terminal 62 and the second end portion 40B of the test coil 40 on the second coil portion 30B side. Both the third connection wiring 63 and the fourth connection wiring 64 are positioned in the X-direction between the first connection wiring 53 and the second connection wiring 54. With this configuration, the same effect as described in (1-5) can be obtained. Therefore, both the third connection wiring 63 and the fourth connection wiring 64 can be shortened.
(1-8) The number of turns of the test coil 40 is fewer than the number of turns of the detection coil 30.
   With this configuration, the test coil 40 can be made smaller. Consequently, the magnetic sensor chip 10 can be miniaturized.
(1-9) The number of turns of the test coil 40 is one.
   With this configuration, the test coil 40 can be further reduced in size. Consequently, the magnetic sensor chip 10 can be further miniaturized.
(1-10) The magnetic sensor chip 10 includes a coil connection wiring 80 that electrically connects the first coil portion 30A and the second coil portion 30B.
   With this configuration, compared to a case where the first coil portion 30A and the second coil portion 30B are electrically connected using wires, the inductance of the conductive path between the first coil portion 30A and the second coil portion 30B can be reduced.
(1-11) The coil connection wiring 80 is positioned in the Y-direction on the side opposite the test terminals 60 and detection terminals 50 relative to the test coil 40 and detection coil 30.
   With this configuration, the coil connection wiring 80 can connect the first coil portion 30A and the second coil portion 30B without bypassing the test terminals 60 and detection terminals 50. Therefore, the conductive path between the first coil portion 30A and the second coil portion 30B can be shortened.
(1-12) The magnetic sensor chip 10 includes a substrate 20 that includes a substrate surface 21. The test coil 40 includes a first test wiring 41 provided on the substrate surface 21 and a second test wiring 42 connected to the first test wiring 41.

With this configuration, one first test wiring 41 and one second test wiring 42 form the coil portion (one turn) of the test coil 40. In other words, a single first test wiring 41 and a single second test wiring 42 constitute a single turn unit of the test coil 40. Therefore, the number of turns of the test coil 40 can be easily adjusted by changing the number of first test wirings 41 and second test wirings 42.
(1-13) The first test wirings 41 and the second test wirings 42 are alternately arranged in the X-direction. The first test wiring 41 extends in a direction intersecting the X-direction in a plan view.
   With this configuration, since one first test wiring 41 and one second test wiring 42 form one turn of the test coil 40, the length of one turn is determined by the lengths of the first test wiring 41 and the second test wiring 42. In this regard, since the first test wiring 41 is provided on the substrate surface 21, the length of the first test wiring 41 can be easily adjusted.
(1-14) The detection coil 30 includes multiple first detection wirings 31 spaced apart in the X-direction and multiple second detection wirings 32, each connected between two adjacent first detection wirings 31 in the X-direction. The multiple first detection wirings 31 are provided on the substrate surface 21.

With this configuration, one first detection wiring 31 and one second detection wiring 32 form the coil portion (one turn) of the detection coil 30. In other words, a single first detection wiring 31 and a single second detection wiring 32 constitute a single turn unit of the detection coil 30. Therefore, the number of turns of the detection coil 30 can be easily adjusted by changing the number of first detection wirings 31 and second detection wirings 32.
(1-15) Each of the multiple first detection wirings 31 extends in a direction intersecting the X-direction in a plan view.
   With this configuration, since one first detection wiring 31 and one second detection wiring 32 form one turn of the detection coil 30, the length of one turn is determined by the lengths of the first detection wiring 31 and the second detection wiring 32. In this regard, since the first detection wiring 31 is provided on the substrate surface 21, the length of the first detection wiring 31 can be easily adjusted.
(1-16) The magnetic sensor chip 10 includes an insulating member 70 that covers the first test wirings 41 and multiple first detection wirings 31. The insulating member 70 is in contact with the substrate surface 21. The second test wiring 42 extends along the surface 71 of the insulating member 70.

With this configuration, the length of the second test wiring 42 is determined by the cross-sectional shape and height of the insulating member 70. Therefore, the length of the second test wiring 42 can be easily adjusted by modifying the shape of the insulating member 70.
(1-17) The second detection wiring 32 extends along the surface 71 of the insulating member 70.
   With this configuration, the length of the second detection wiring 32 is determined by the cross-sectional shape and height of the insulating member 70. Therefore, the length of the second detection wiring 32 can be easily adjusted by modifying the shape of the insulating member 70.
(1-18) In the detection coil 30, the width W13 of the third end portion 32A of the second detection wiring 32 is narrower than the width W11 of the first end portion 31A of the first detection wiring 31.
   With this configuration, even if the formation position of the third end portion 32A shifts in the X-direction due to manufacturing errors, the third end portion 32A can still be placed on the first end portion 31A.
(1-19) In the detection coil 30, the length L13 of the third end portion 32A of the second detection wiring 32 is shorter than the length L11 of the first end portion 31A of the first detection wiring 31.
   With this configuration, even if the formation position of the third end portion 32A shifts in the Y-direction due to manufacturing errors, the third end portion 32A can still be placed on the first end portion 31A.
(1-20) In the detection coil 30, the width W14 of the fourth end portion 32B of the second detection wiring 32 is narrower than the width W12 of the second end portion 31B of the first detection wiring 31.
   With this configuration, even if the formation position of the fourth end portion 32B shifts in the X-direction due to manufacturing errors, the fourth end portion 32B can still be placed on the second end portion 31B.
(1-21) In the detection coil 30, the length L14 of the fourth end portion 32B of the second detection wiring 32 is shorter than the length L12 of the second end portion 31B of the first detection wiring 31.
   With this configuration, even if the formation position of the fourth end portion 32B shifts in the Y-direction due to manufacturing errors, the fourth end portion 32B can still be placed on the second end portion 31B.
(1-22) In the test coil 40, the width W23 of the third end portion 42A of the second test wiring 42 is narrower than the width W21 of the first end portion 41A of the first test wiring 41. With this configuration, even if the formation position of the third end portion 42A shifts in the X-direction due to manufacturing errors, the third end portion 42A can still be placed on the first end portion 41A.
(1-23) In the test coil 40, the length L23 of the third end portion 42A of the second test wiring 42 is shorter than the length L21 of the first end portion 41A of the first test wiring 41. With this configuration, even if the formation position of the third end portion 42A shifts in the Y-direction due to manufacturing errors, the third end portion 42A can still be placed on the first end portion 41A.
(1-24) In the test coil 40, the width W24 of the fourth end portion 42B of the second test wiring 42 is narrower than the width W22 of the second end portion 41B of the first test wiring 41.
   With this configuration, even if the formation position of the fourth end portion 42B shifts in the X-direction due to manufacturing errors, the fourth end portion 42B can still be placed on the second end portion 41B.
(1-25) In the test coil 40, the length L24 of the fourth end portion 42B of the second test wiring 42 is shorter than the length L22 of the second end portion 41B of the first test wiring 41.

With this configuration, even if the formation position of the fourth end portion 42B shifts in the Y-direction due to manufacturing errors, the fourth end portion 42B can still be placed on the second end portion 41B.

### Second Embodiment

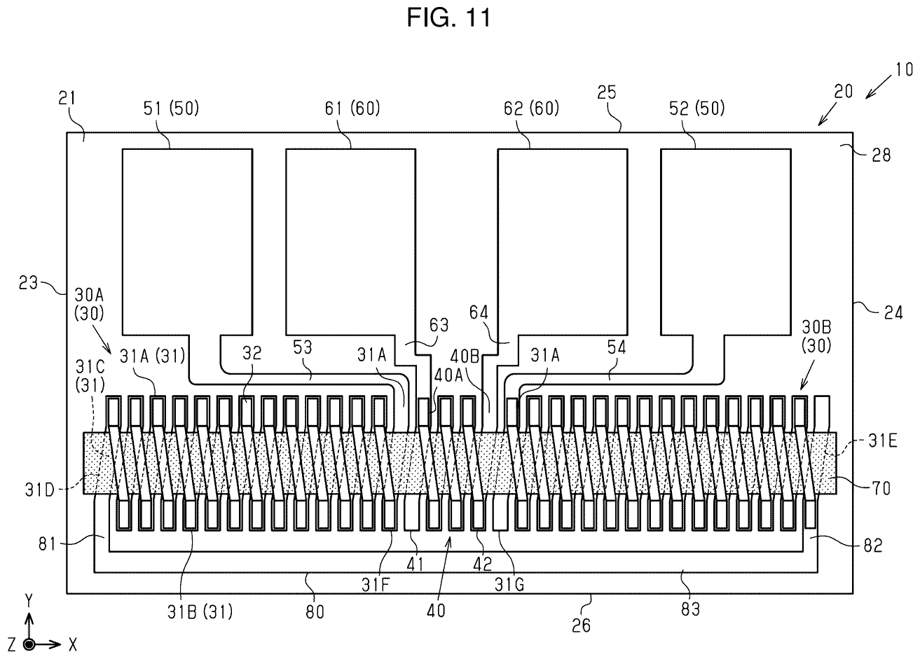

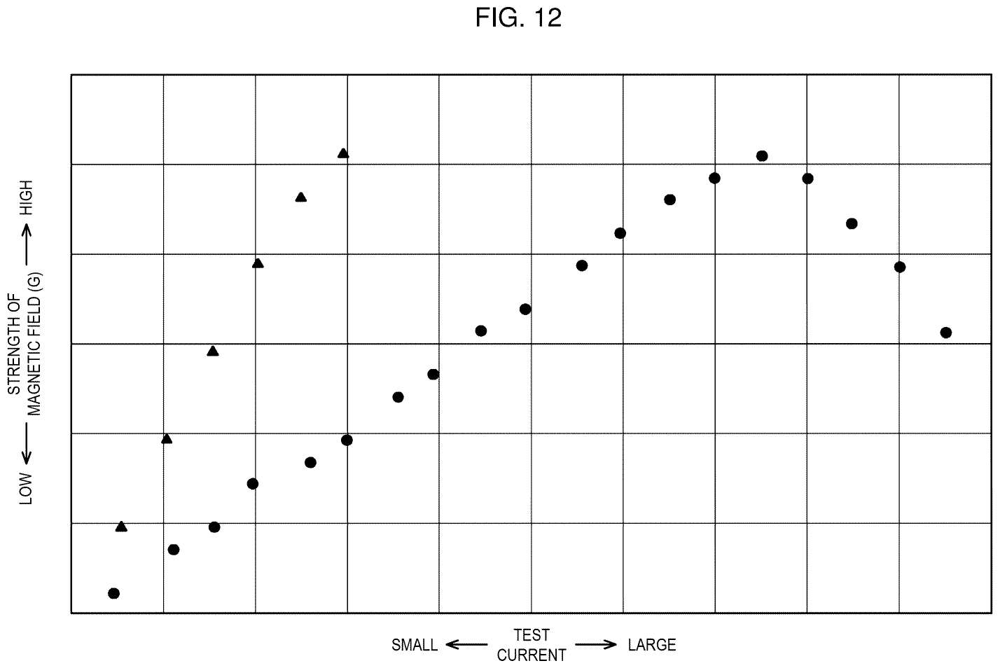

With reference to FIGS. 11 and 12, the magnetic sensor chip 10 of the second embodiment will be described. The magnetic sensor chip 10 of the second embodiment differs primarily from the magnetic sensor chip 10 of the first embodiment in the configuration of the test coil 40. The following sections provide a detailed description of the test coil 40 configuration, while components common to the first embodiment are assigned the same reference numerals, and their descriptions are omitted.

FIG. 11 schematically illustrates the planar structure of the magnetic sensor chip 10 of the second embodiment.

As shown in FIG. 11, the number of turns of the test coil 40 may be two or more. In the second embodiment, the test coil 40 has three turns. That is, the number of turns of the test coil 40 is fewer than the number of turns of the detection coil 30. The number of turns of the test coil 40 is also fewer than the number of turns of the first coil portion 30A and the second coil portion 30B.

The test coil 40 includes four first test wirings 41 and three second test wirings 42. The material composition of each first test wiring 41 and each second test wiring 42 is the same as in the first embodiment. The shape and size of each first test wiring 41 and each second test wiring 42 are also the same as in the first embodiment. The first end portion 41A of the first test wiring 41 closest to the first coil portion 30A constitutes the first end portion 40A of the test coil 40. The first end portion 41A of the first test wiring 41 closest to the second coil portion 30B constitutes the second end portion 40B of the test coil 40.

The three second test wirings 42 are spaced apart from each other in the X-direction. The connection method between the second test wirings 42 and the first test wirings 41 is the same as in the first embodiment. Each second test wiring 42 extends along the surface of the insulating member 70, as in the first embodiment.

FIG. 12 is a graph illustrating the relationship between the test current and the magnetic field for cases where the number of turns of the test coil 40 is one and where the number of turns of the test coil 40 is three. In FIG. 12, the circular markers indicate the case where the number of turns of the test coil 40 is one, and the triangular markers indicate the case where the number of turns of the test coil 40 is three.

As shown in FIG. 12, when the number of turns of the test coil 40 is three, the magnetic field generated by the test coil 40 due to the test current is stronger compared to the case where the number of turns is one. In other words, when the number of turns of the test coil 40 is three, the required magnitude of the test current to generate a predetermined induced voltage in the detection coil 30 is smaller than in the case where the number of turns of the test coil 40 is one.

On the other hand, in the case where the number of turns of the test coil 40 is one, the strength of the magnetic field generated by the test coil 40 increases as the test current increases. However, beyond a certain test current, the strength of the magnetic field decreases as the test current increases. This phenomenon is likely due to a reduction in the magnetic field strength generated by the test coil 40 caused by heat generated as the test current increases.

### Effects of the Second Embodiment

According to the magnetic sensor chip 10 of the second embodiment, the following effects can be obtained.
(2-1) The number of turns of the test coil 40 is two or more.

With this configuration, compared to the case where the number of turns of the test coil 40 is one, the strength of the magnetic field generated by the test coil 40 for the same magnitude of test current increases. The test current supplied to the test coil 40 to generate a predetermined induced voltage in the detection coil 30 can be reduced. Therefore, the risk of the test coil 40 breaking due to an excessively high test current can be prevented.
(2-2) The number of turns of the test coil 40 is three.
   With this configuration, the test current supplied to the test coil 40 to generate a predetermined induced voltage in the detection coil 30 can be reduced, while also enabling miniaturization of the magnetic sensor chip 10 in the X-direction.

### Third Embodiment

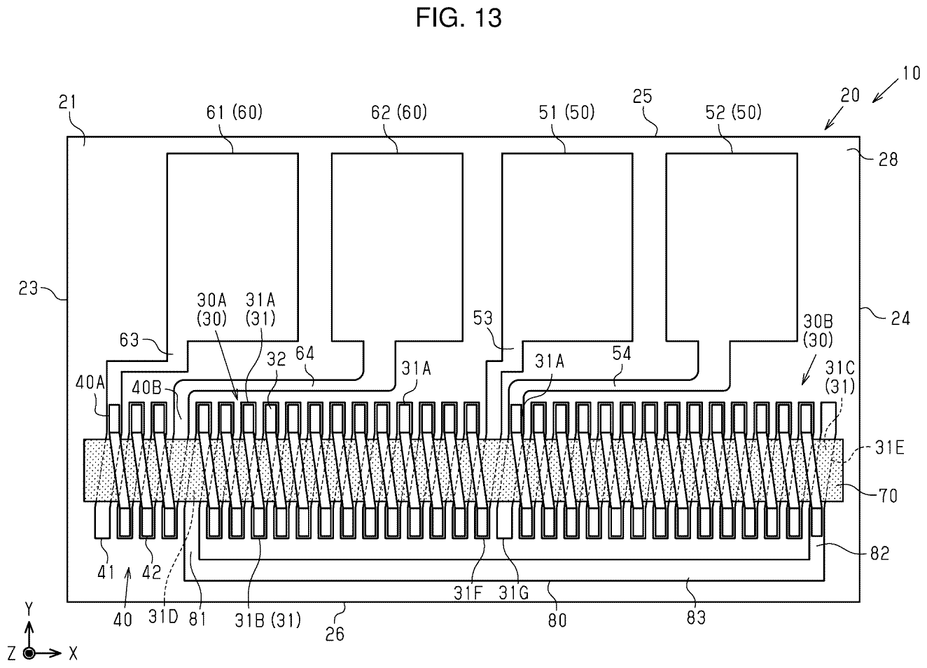

With reference to FIG. 13, the magnetic sensor chip 10 of the third embodiment will be described. The magnetic sensor chip 10 of the third embodiment primarily differs from the magnetic sensor chip 10 of the second embodiment in the arrangement of the test coil 40 and the test terminal 60. The following sections describe these differences, while components common to the second embodiment are assigned the same reference numerals, and their descriptions are omitted.

FIG. 13 schematically illustrates the planar structure of the magnetic sensor chip 10 of the third embodiment.

As shown in FIG. 13, the test coil 40 is positioned closer to the first substrate side surface 23 of the substrate 20 than the detection coil 30. In other words, the first coil portion 30A of the detection coil 30 is positioned between the test coil 40 and the second coil portion 30B in the X-direction. The test coil 40 is positioned closer to the first substrate side surface 23 than the coil connection wiring 80 in the X-direction.

In the third embodiment, the first end portion 40A of the test coil 40 is positioned on the side opposite the first coil portion 30A in the X-direction. The second end portion 40B of the test coil 40 is positioned on the side of the first coil portion 30A in the X-direction. The configuration of the multiple first test wirings 41 and multiple second test wirings 42 in the test coil 40 is the same as in the second embodiment.

The test terminals 60 are positioned closer to the first substrate side surface 23 of the substrate 20 than the detection terminals 50. In other words, the first detection terminal 51 is positioned in the X-direction between the test terminals 60 and the second detection terminal 52. The first test terminal 61 and the second test terminal 62 are positioned closer to the first substrate side surface 23 than the first detection terminal 51.

Both the first detection terminal 51 and the second detection terminal 52 are positioned closer to the second substrate side surface 24 than the center of the substrate 20 in the X-direction. The first detection terminal 51 and the second detection terminal 52 are arranged side by side in the X-direction. Both the first detection terminal 51 and the second detection terminal 52 are positioned closer to the second coil portion 30B than the first coil portion 30A in the X-direction. Both the first detection terminal 51 and the second detection terminal 52 are positioned at the same location as the second coil portion 30B in the Y-direction.

Both the first test terminal 61 and the second test terminal 62 are positioned closer to the first substrate side surface 23 than the center of the substrate 20 in the X-direction. The first test terminal 61 and the second test terminal 62 are arranged side by side in the X-direction. Both the first test terminal 61 and the second test terminal 62 are positioned closer to the first coil portion 30A than the second coil portion 30B in the X-direction. Both the first test terminal 61 and the second test terminal 62 are positioned at the same location as the first coil portion 30A in the Y-direction.

According to the third embodiment, the same effects as those in (1-1) to (1-3), (1-6), (1-8), (1-10) to (1-25) of the first embodiment, as well as those of the second embodiment, can be obtained.

### Fourth Embodiment

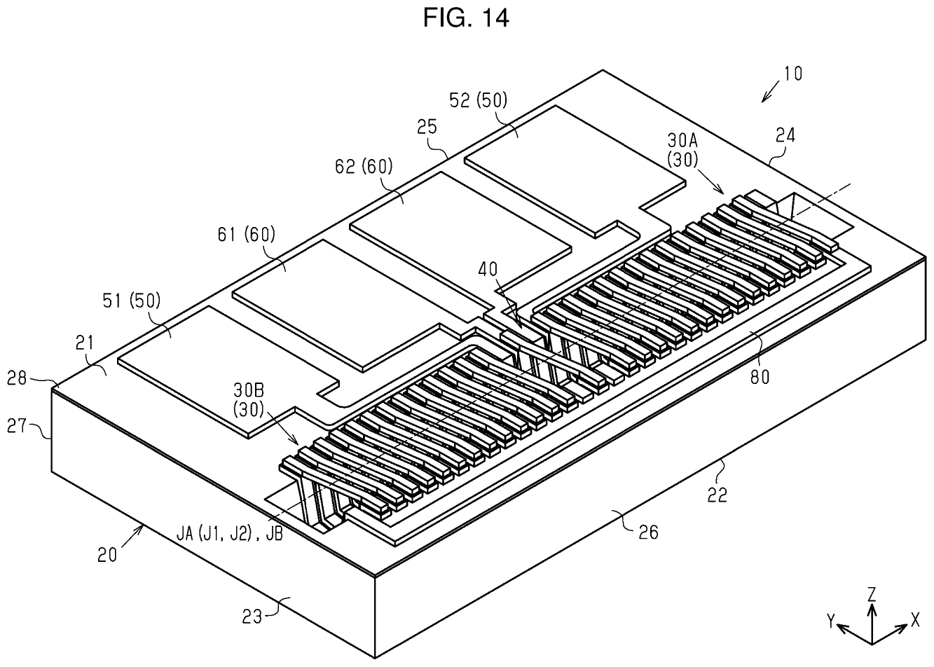

With reference to FIGS. 14 to 17, the magnetic sensor chip 10 of the fourth embodiment will be described. The magnetic sensor chip 10 of the fourth embodiment primarily differs from the magnetic sensor chip 10 of the first embodiment in the configuration of the substrate 20, the detection coil 30, the test coil 40, and the insulating member 70. The following sections describe these differences, while components common to the first embodiment are assigned the same reference numerals, and their descriptions are omitted.

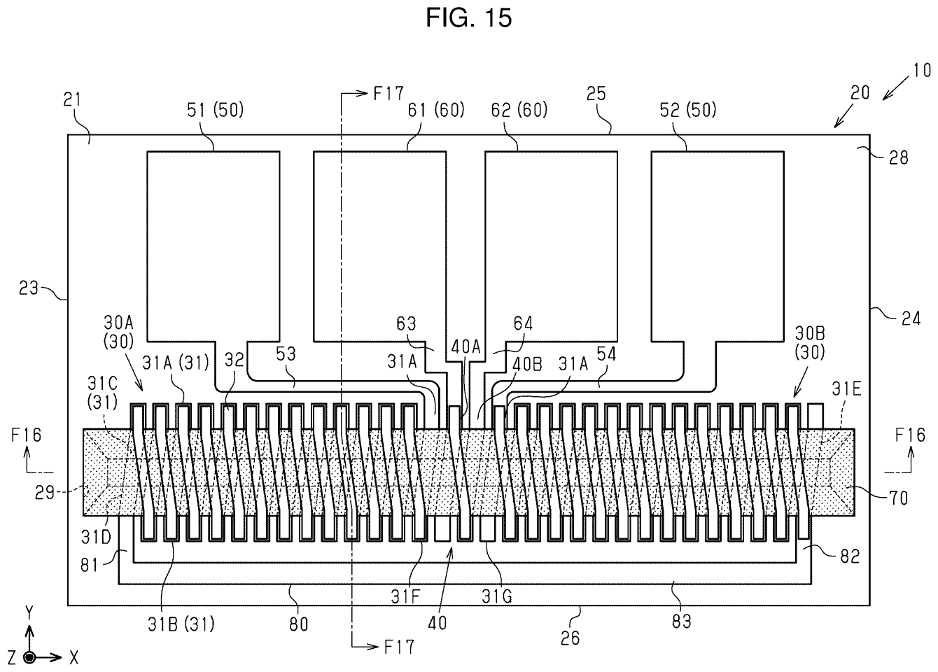

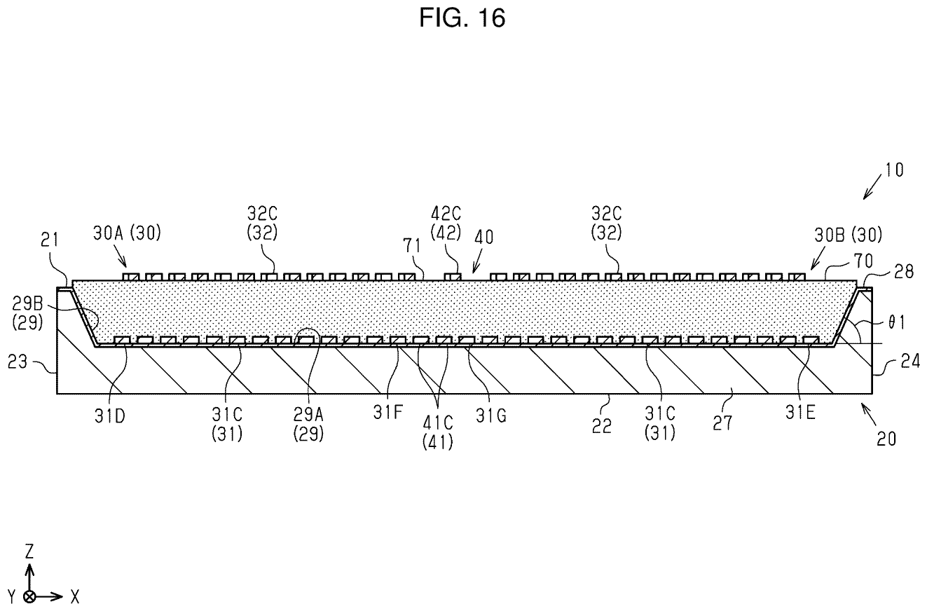

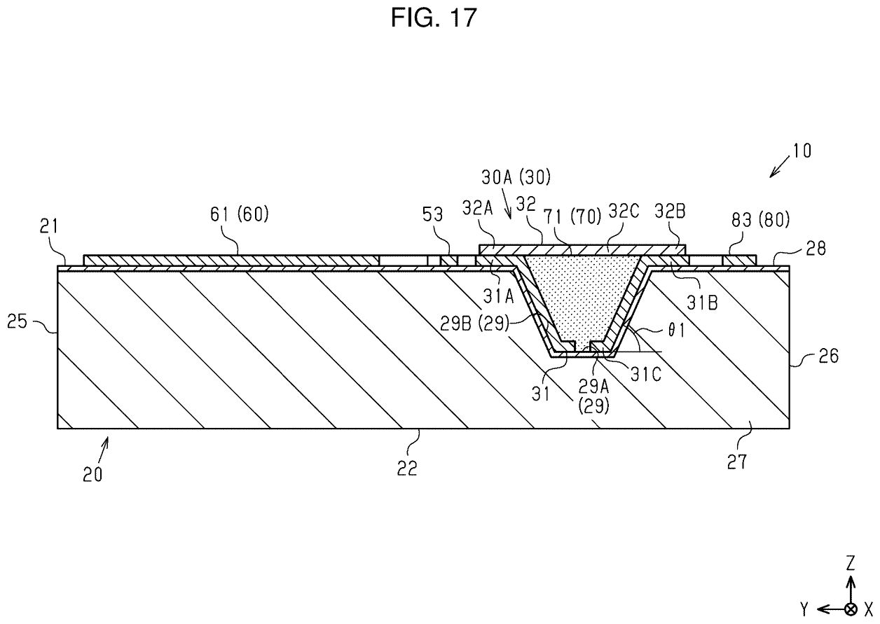

FIG. 14 schematically illustrates the perspective structure of the magnetic sensor chip 10 of the fourth embodiment. FIG. 15 schematically illustrates the planar structure of the magnetic sensor chip 10 in FIG. 14. FIG. 16 schematically illustrates the sectional structure of the magnetic sensor chip 10 taken along line F16-F16 of FIG. 15. FIG. 17 schematically illustrates the sectional structure of the magnetic sensor chip 10 taken along line F17-F17 of FIG. 15.

### Substrate

As shown in FIGS. 14 to 17, the substrate 20 includes a recess 29 that extends from the substrate surface 21 toward the substrate back surface 22. The recess 29 extends in a strip shape along the X-direction in a plan view. The recess 29 is provided so as to pass through both the detection coil 30 and the test coil 40 in the X-direction in a plan view.

The recess 29 includes a bottom surface 29A and side surfaces 29B that connect the bottom surface 29A to the substrate surface 21. The bottom surface 29A extends in a strip shape along the X-direction in a plan view. Four side surfaces 29B are provided along the edges of the bottom surface 29A. The pair of side surfaces 29B facing each other in the X-direction are inclined so that they move apart as they extend from the bottom surface 29A toward the substrate surface 21. Similarly, the pair of side surfaces 29B facing each other in the Y-direction are inclined so that they move apart as they extend from the bottom surface 29A toward the substrate surface 21.

The substrate body 27 of the substrate 20 in the fourth embodiment is composed of a single-crystal semiconductor material. In the fourth embodiment, the substrate body 27 is an Si substrate. The recess 29 is formed by etching (anisotropic etching) the substrate body 27. More specifically, the substrate surface 21 of the substrate 20 is a plane based on the crystal structure of Si and corresponds to the (100) plane. The side surfaces 29B of the recess 29 correspond to the (111) planes. Therefore, the inclination angle θ1 of the side surfaces 29B relative to the bottom surface 29A is determined by the crystal structure of the Si substrate and is approximately 54.7°.

The insulating film 28 provided on the substrate body 27 covers the substrate surface 21, the four side surfaces 29B of the recess 29, and the bottom surface 29A. The insulating film 28 is composed of SiO₂. The insulating film 28 is formed, for example, by thermally oxidizing the substrate body 27 after forming the recess 29. Alternatively, the insulating film 28 may be composed of insulating materials such as SiN or AlN.

### Detection Coil, Test Coil, and Insulating Member

As shown in FIGS. 14 to 17, the first detection wiring 31 of the detection coil 30 and the first test wiring 41 of the test coil 40 are provided across the substrate surface 21, the side surfaces 29B of the recess 29, and the bottom surface 29A. The first detection wiring 31 and the first test wiring 41 extend along the surface of the recess 29. Here, the surface of the recess 29 refers to the bottom surface 29A and the side surfaces 29B of the recess 29. More specifically, the first end portion 31A and the second end portion 31B of the first detection wiring 31 are provided on the substrate surface 21. The first conductor portion 31C of the first detection wiring 31 is provided on the side surfaces 29B and bottom surface 29A of the recess 29. The first conductor portion 31C extends along the surface of the recess 29.

The insulating member 70 is provided to fill the recess 29. The insulating member 70 penetrates both the detection coil 30 and the test coil 40 in the X-direction in a plan view. The insulating member 70 covers the first detection wiring 31 of the detection coil 30 and the first test wiring 41 of the test coil 40. More specifically, the insulating member 70 covers the first conductor portion 31C of the first detection wiring 31 and the first conductor portion 41C of the first test wiring 41. The first end portion 31A and the second end portion 31B of the first detection wiring 31, as well as the first end portion 41A and the second end portion 41B of the first test wiring 41, are exposed from the insulating member 70.

In the fourth embodiment, the surface 71 of the insulating member 70 is a planar surface orthogonal to the Z-direction. The Z-direction position of the surface 71 of the insulating member 70 is the same as the Z-direction positions of both the first end portion 31A and the second end portion 31B of the first detection wiring 31, as well as the first end portion 41A and the second end portion 41B of the first test wiring 41. The Z-direction position of the surface 71 of the insulating member 70 can be adjusted as needed.

The second detection wiring 32 of the detection coil 30 is provided on the surface 71 of the insulating member 70. More specifically, the second conductor portion 32C of the second detection wiring 32 is provided on the surface 71 of the insulating member 70. The third end portion 32A of the second detection wiring 32 is positioned closer to the detection terminal 50 than the insulating member 70. The third end portion 32A is connected to the first end portion 31A of the first detection wiring 31. The fourth end portion 32B of the second detection wiring 32 is positioned on the opposite side of the insulating member 70 from the detection terminal 50. The fourth end portion 32B is connected to the second end portion 31B of an adjacent first detection wiring 31 to which the third end portion 32A is connected.

The second test wiring 42 of the test coil 40 is provided on the surface 71 of the insulating member 70. More specifically, the second conductor portion 42C of the second test wiring 42 is provided on the surface 71 of the insulating member 70. The third end portion 42A of the second test wiring 42 is positioned closer to the test terminal 60 than the insulating member 70. The third end portion 42A is connected to the first end portion 41A of the first test wiring 41. The fourth end portion 42B of the second test wiring 42 is positioned on the opposite side of the insulating member 70 from the test terminal 60. The fourth end portion 42B is connected to the second end portion 41B of an adjacent first test wiring 41 to which the third end portion 42A is connected.

### Effects of the Fourth Embodiment

According to the magnetic sensor chip 10 of the fourth embodiment, the following effects can be obtained.
(4-1) The substrate 20 includes a substrate back surface 22 opposite the substrate surface 21 and a recess 29 that extends from the substrate surface 21 toward the substrate back surface 22. The first test wiring 41 and the first detection wiring 31 extend along the surface of the recess 29.

With this configuration, the lengths of the first test wiring 41 and the first detection wiring 31 are determined by the depth of the recess 29. Additionally, the lengths of the first test wiring 41 and the first detection wiring 31 are determined by the opening width of the recess 29 in the Y-direction. Therefore, by adjusting the depth and opening width of the recess 29, the turn length of the detection coil 30 and the turn length of the test coil 40 can be adjusted accordingly.
(4-2) The insulating member 70 is embedded within the recess 29. The insulating member 70 covers the first test wiring 41 and the multiple first detection wirings 31. Both the second test wiring 42 and the second detection wiring 32 extend along the surface 71 of the insulating member 70.

With this configuration, the position of the insulating member 70 is determined by the position of the recess 29. As a result, compared to a case where the insulating member 70 is provided directly on the substrate surface 21, the positional accuracy of the insulating member 70 can be improved. Consequently, the positional accuracy of the second test wiring 42 relative to the first test wiring 41 and the positional accuracy of the second detection wiring 32 relative to the first detection wiring 31 can be improved. Additionally, since the protruding height of the insulating member 70 above the substrate surface 21 can be reduced, the overall thickness of the magnetic sensor chip 10 can be minimized.

### Fifth Embodiment

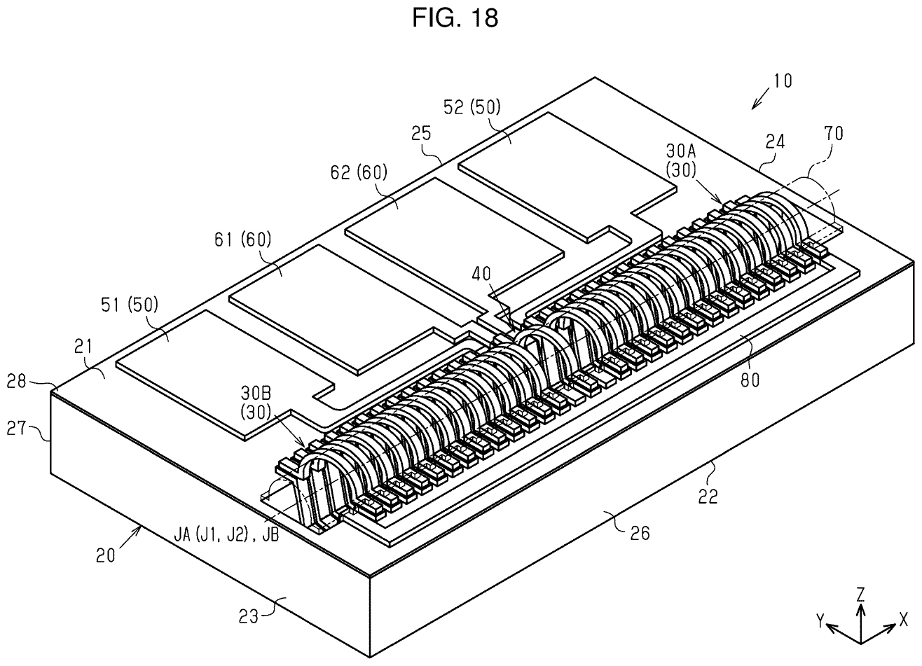

With reference to FIGS. 18 to 21, the magnetic sensor chip 10 of the fifth embodiment will be described. The magnetic sensor chip 10 of the fifth embodiment primarily differs from the magnetic sensor chip 10 of the first embodiment in the configuration of the detection coil 30, the test coil 40, and the insulating member 70. The following sections describe these differences, while components common to the first embodiment are assigned the same reference numerals, and their descriptions are omitted.

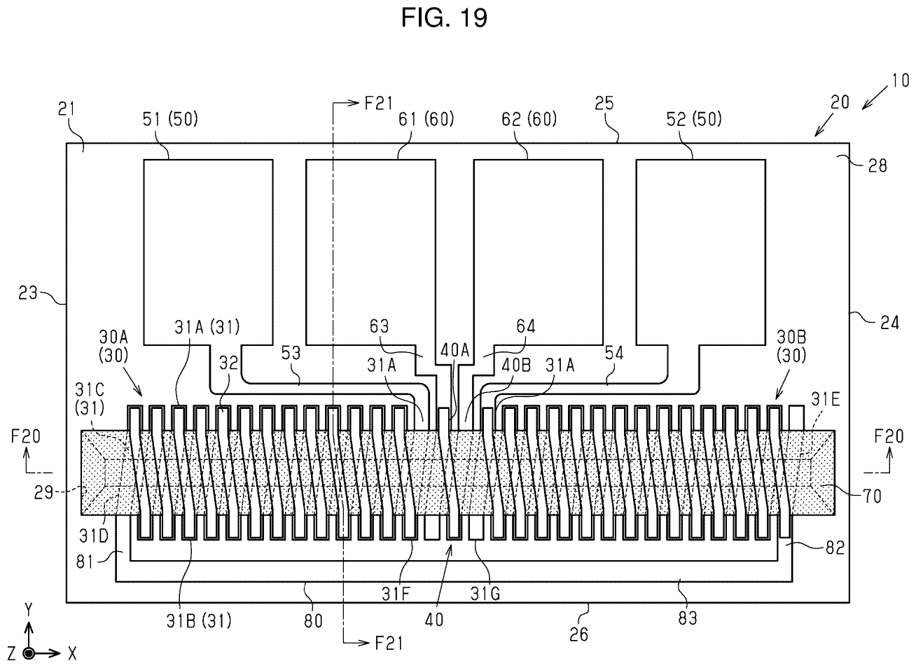

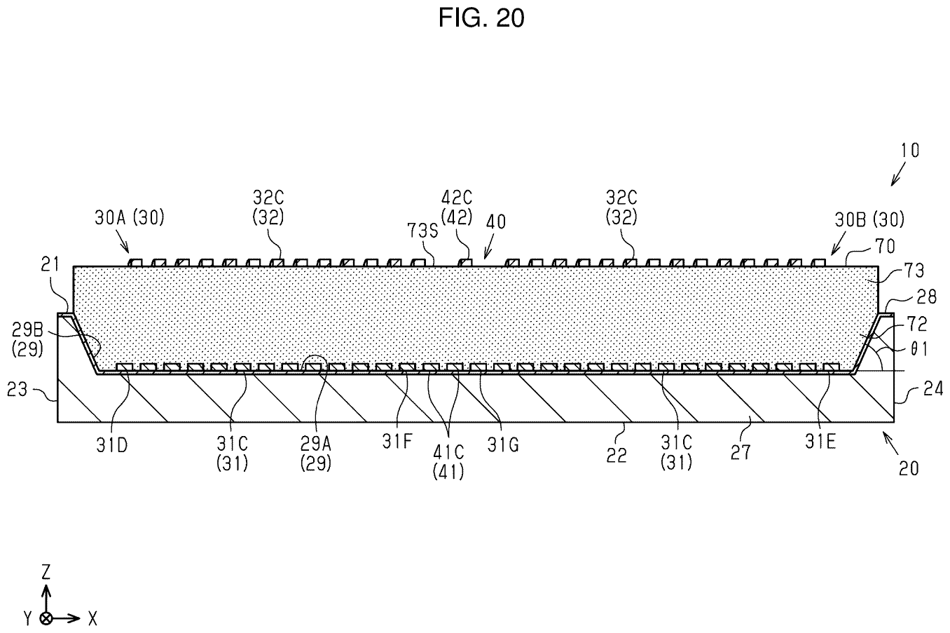

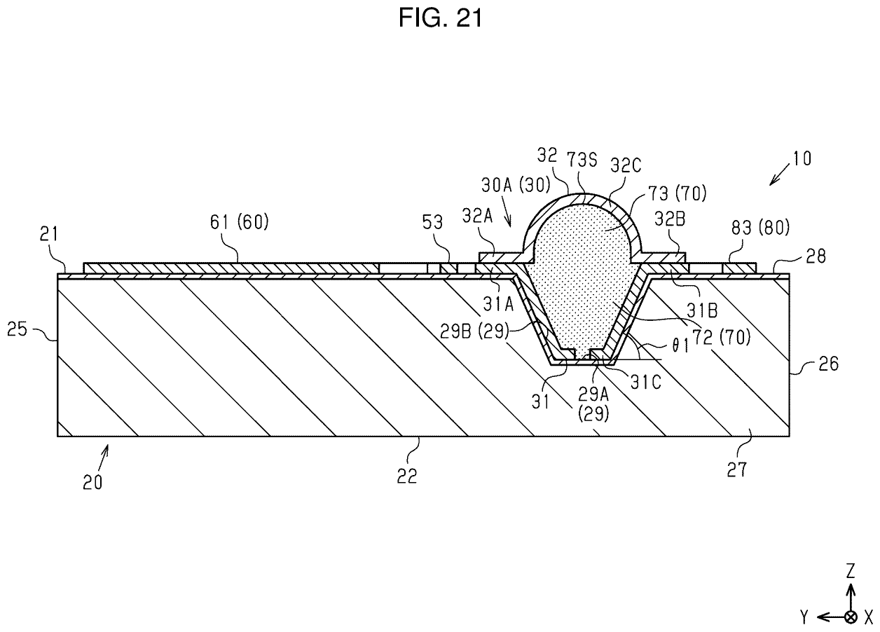

FIG. 18 schematically illustrates the perspective structure of the magnetic sensor chip 10 of the fifth embodiment. FIG. 19 schematically illustrates the planar structure of the magnetic sensor chip 10 in FIG. 18. FIG. 20 schematically illustrates the sectional structure of the magnetic sensor chip 10 taken along line F20-F20 of FIG. 18. FIG. 21 schematically illustrates the sectional structure of the magnetic sensor chip 10 taken along line F21-F21 of FIG. 18.

### Detection Coil, Test Coil, and Insulating Member

As shown in FIGS. 18 to 21, the first detection wiring 31 of the detection coil 30 and the first test wiring 41 of the test coil 40 are the same as those in the fourth embodiment.

The insulating member 70 includes an embedded insulating portion 72 that fills the recess 29 and a protruding insulating portion 73 that extends outward from the embedded insulating portion 72 in the direction opposite to the substrate back surface 22. The protruding insulating portion 73 has an arc-shaped cross-sectional profile that expands away from the substrate surface 21 in a plane (YZ plane) perpendicular to the X-direction, similar to the insulating member 70 in the first embodiment.

The second detection wiring 32 of the detection coil 30 is provided on the surface 73S of the protruding insulating portion 73. The second detection wiring 32 extends along the surface 73S of the protruding insulating portion 73, which has an arc-shaped cross-section in a plane (YZ plane) perpendicular to the X-direction. As a result, the second detection wiring 32 is positioned away from the first detection wiring 31 in the Z-direction due to the insulating member 70.

The second test wiring 42 of the test coil 40 is provided on the surface 73S of the protruding insulating portion 73. The second test wiring 42 extends along the surface 73S of the protruding insulating portion 73, which has an arc-shaped cross-section in a plane (YZ plane) perpendicular to the X-direction. As a result, the second test wiring 42 is positioned away from the first test wiring 41 in the Z-direction due to the insulating member 70.

### Effects of the Fifth Embodiment

According to the magnetic sensor chip 10 of the fifth embodiment, the following effects can be obtained.
(5-1) The insulating member 70 includes an embedded insulating portion 72 that fills the recess 29 and a protruding insulating portion 73 that extends outward from the embedded insulating portion 72 in the direction opposite to the substrate back surface 22.

With this configuration, the length of one turn of the detection coil 30, which is formed by the first detection wiring 31 extending along the recess 29 and the second detection wiring 32 extending along the surface 73S of the protruding insulating portion 73, can be increased. Similarly, the length of one turn of the test coil 40, which is formed by the first test wiring 41 extending along the recess 29 and the second test wiring 42 extending along the surface 73S of the protruding insulating portion 73, can be increased.

### MODIFICATIONS

The above-described embodiments can be modified as follows. The above embodiments and the following modifications can be combined as long as there are no technical contradictions. In the following modifications, common elements with the above embodiments are assigned the same reference numerals, and their descriptions are omitted.

In each embodiment, the structure of the portion of the insulating member 70 corresponding to the detection coil 30 and the structure of the portion corresponding to the test coil 40 may differ.

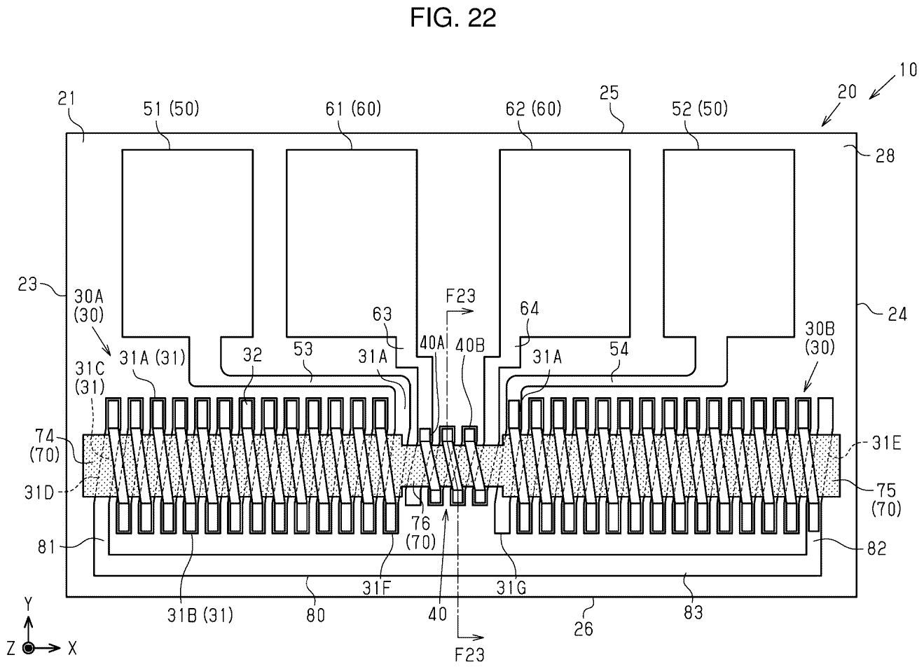

In one example, as shown in FIG. 22, the insulating member 70 includes a first coil insulating portion 74 corresponding to the first coil portion 30A of the detection coil 30, a second coil insulating portion 75 corresponding to the second coil portion 30B, and a test insulating portion 76 corresponding to the test coil 40. The first coil insulating portion 74 penetrates the first coil portion 30A in the X-direction. The second coil insulating portion 75 penetrates the second coil portion 30B in the X-direction. The test insulating portion 76 is positioned between the first coil insulating portion 74 and the second coil insulating portion 75 in the X-direction. The test insulating portion 76 penetrates the test coil 40 in the X-direction.

In a plan view, the width (Y-direction dimension) of the test insulating portion 76 is smaller than the widths (Y-direction dimensions) of the first coil insulating portion 74 and the second coil insulating portion 75. The width of the first coil insulating portion 74 is equal to the width of the second coil insulating portion 75.

The second detection wiring 32 of the first coil portion 30A extends along the surface of the first coil insulating portion 74. The second detection wiring 32 of the second coil portion 30B extends along the surface of the second coil insulating portion 75. The second test wiring 42 of the test coil 40 extends along the surface of the test insulating portion 76. As a result, the coil diameter of the test coil 40 is smaller than the coil diameters of the first coil portion 30A and the second coil portion 30B. Here, the coil diameter of the test coil 40 can be defined, for example, by the distance in the Y-direction between the third end portion 42A and the fourth end portion 42B of the second test wiring 42 in a plan view. The coil diameter of the first coil portion 30A can be defined, for example, by the distance in the Y-direction between the third end portion 32A and the fourth end portion 32B of the second detection wiring 32 of the first coil portion 30A in a plan view. The coil diameter of the second coil portion 30B can be defined similarly.

According to the modification shown in FIG. 22, reducing the coil diameter of the test coil 40 increases the magnetic field strength generated by the test coil 40. Therefore, the test current supplied to the test coil 40 can be reduced while still generating a predetermined induced voltage in the detection coil 30.

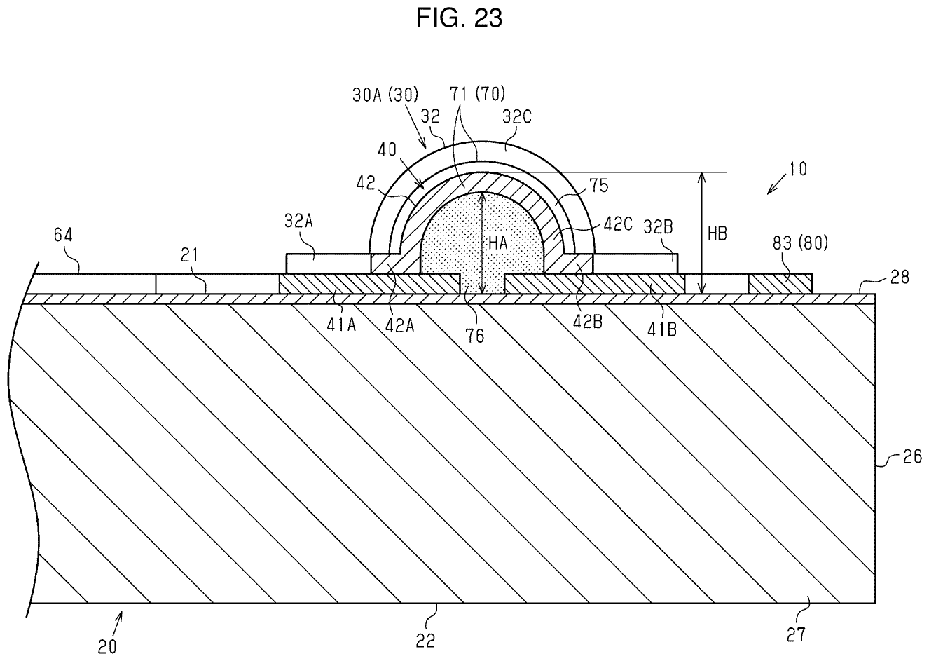

In one example, as shown in FIG. 23, the protruding height HA of the test insulating portion 76 may be smaller than the protruding height HB of the second coil insulating portion 75. Even in this case, the coil diameter of the test coil 40 remains smaller than the coil diameter of the second coil portion 30B. Although not shown in the figure, the protruding height HA of the test insulating portion 76 may also be smaller than the protruding height of the first coil insulating portion 74. In this case, the coil diameter of the test coil 40 is smaller than the coil diameter of the first coil portion 30A. The protruding height of the first coil insulating portion 74 may be equal to the protruding height HB of the second coil insulating portion 75.

In the modification shown in FIG. 23, the width (Y-direction dimension) of the test insulating portion 76 may be equal to the width (Y-direction dimension) of the first coil insulating portion 74. Additionally, in the modification shown in FIG. 22, the protruding height HA of the test insulating portion 76 may be equal to the protruding height HB of the first coil insulating portion 74.

In each embodiment, the cross-sectional shape of the insulating member 70 in a plane (YZ plane) perpendicular to the X-direction can be arbitrarily modified. In one example, the cross-sectional shape of the insulating member 70 may be rectangular.

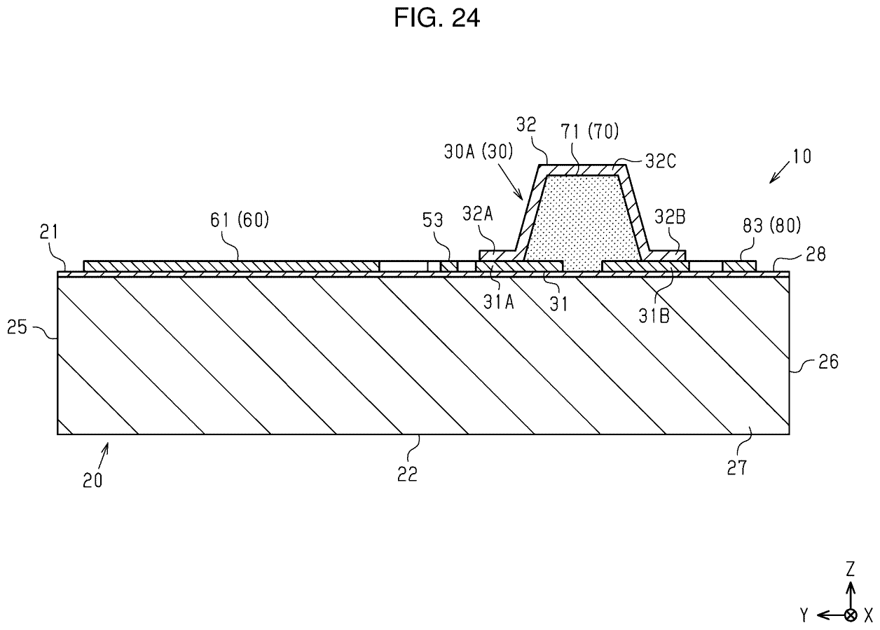

In one example, as shown in FIG. 24, the cross-sectional shape of the insulating member 70 is trapezoidal, with the Y-direction length gradually decreasing as it extends away from the substrate surface 21. The second detection wiring 32 of the detection coil 30 extends along the surface of the trapezoidal insulating member 70. Although not shown in the figure, the second test wiring 42 of the test coil 40 similarly extends along the surface of the trapezoidal insulating member 70.

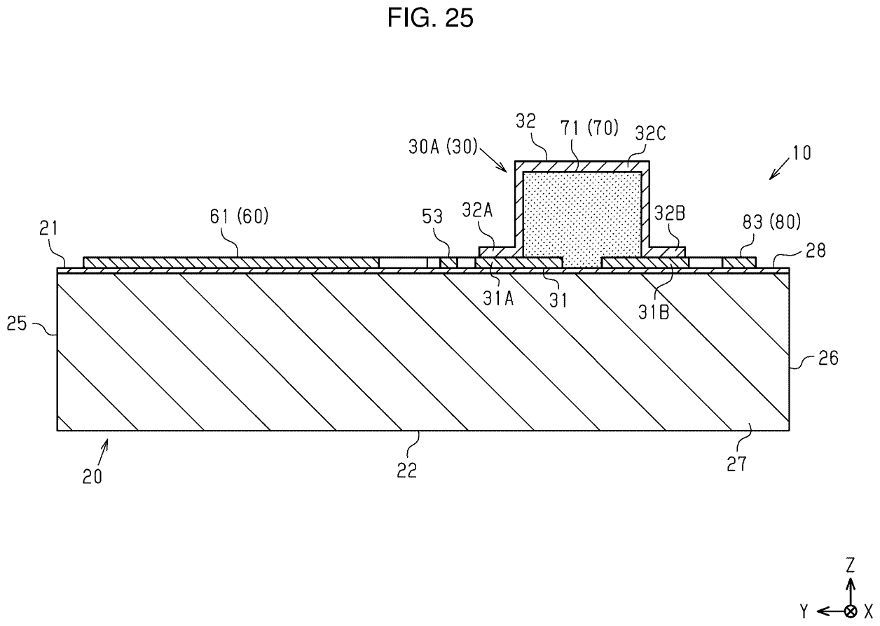

In one example, as shown in FIG. 25, the cross-sectional shape of the insulating member 70 is rectangular. The second detection wiring 32 of the detection coil 30 extends along the surface of the rectangular insulating member 70. Although not shown in the figure, the second test wiring 42 of the test coil 40 similarly extends along the surface of the rectangular insulating member 70.

The cross-sectional shape of the insulating member 70 is not limited to the trapezoidal shape shown in FIG. 24 or the rectangular shape shown in FIG. 25. The cross-sectional shape of the insulating member 70 may be triangular or a polygon with five or more sides. Additionally, the insulating member 70 may have a cross-sectional shape that includes both straight and curved (arc-shaped) surfaces. The cross-sectional shape of the protruding insulating portion 73 of the insulating member 70 in the fifth embodiment, in a plane (YZ plane) perpendicular to the X-direction, can also be arbitrarily modified. In one example, the cross-sectional shape of the protruding insulating portion 73 may be rectangular. In another example, the protruding insulating portion 73 may have the cross-sectional shape shown in FIG. 24 or FIG. 25.

In the fifth embodiment, the configuration of the recess 29 and the insulating member 70 can be arbitrarily modified. In one example, the portion of the recess 29 corresponding to the test coil 40 may be omitted. As a result, the embedded insulating portion 72 corresponding to the test coil 40 in the insulating member 70 is omitted, and the first test wiring 41 of the test coil 40 is provided on the substrate surface 21. With this configuration, the coil diameter of the test coil 40 can be reduced. In another example, the protruding insulating portion 73 corresponding to the test coil 40 in the insulating member 70 may be omitted. With this configuration, the coil diameter of the test coil 40 can be reduced.

In the third embodiment, the configuration of the test coil 40 can be arbitrarily modified. In one example, the number of turns of the test coil 40 may be two or fewer. In another example, the test coil 40 may have the same configuration as the test coil 40 in the first embodiment. That is, the number of turns of the test coil 40 may be one.

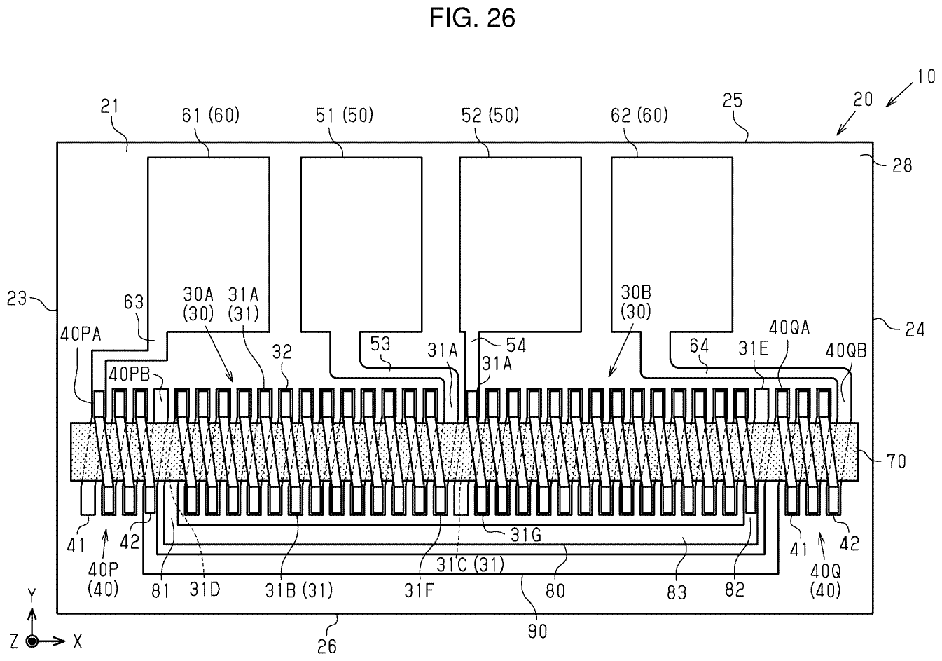

In the third embodiment, as shown in FIG. 26, the test coil 40 includes a first test coil 40P and a second test coil 40Q, which are spaced apart in the X-direction. The detection coil 30 is positioned between the first test coil 40P and the second test coil 40Q in the X-direction. That is, the first coil portion 30A and the second coil portion 30B are positioned between the first test coil 40P and the second test coil 40Q in the X-direction. The first test coil 40P is positioned adjacent to the first coil portion 30A in the X-direction. The second test coil 40Q is positioned adjacent to the second coil portion 30B in the X-direction.

The first test coil 40P includes a first end portion 40PA and a second end portion 40PB. The first end portion 40PA is the end portion of the first test coil 40P opposite to the first coil portion 30A in the X-direction. The second end portion 40PB is the end portion of the first test coil 40P on the side of the first coil portion 30A in the X-direction. The first test coil 40P includes multiple first test wirings 41 and multiple second test wirings 42. Among the multiple first test wirings 41, the one positioned at the end portion opposite to the first coil portion 30A in the X-direction constitutes the first end portion 40PA. Among the multiple first test wirings 41, the one positioned at the end on the first coil portion 30A side in the X-direction constitutes the second end portion 40PB.

The second test coil 40Q includes a first end portion 40QA and a second end portion 40QB. The first end portion 40QA is the end portion of the second test coil 40Q on the side of the second coil portion 30B in the X-direction. The second end portion 40QB is the end portion of the second test coil 40Q opposite to the second coil portion 30B in the X-direction. The second test coil 40Q includes multiple first test wirings 41 and multiple second test wirings 42. Among the multiple first test wirings 41, the one positioned at the end on the second coil portion 30B side in the X-direction constitutes the first end portion 40QA. Among the multiple first test wirings 41, the one positioned at the end portion opposite to the second coil portion 30B in the X-direction constitutes the second end portion 40QB.

The first test coil 40P and the second test coil 40Q are electrically connected to each other. Specifically, the first test coil 40P and the second test coil 40Q are connected via a test coil connection wiring 90. The test coil connection wiring 90 is positioned in the Y-direction on the side opposite the test terminals 60 and the detection terminals 50 relative to the test coil 40 and the detection coil 30. The test coil connection wiring 90 is provided on the substrate surface 21 of the substrate 20. In a plan view, the test coil connection wiring 90 is arranged so as to surround the coil connection wiring 80.

The test coil connection wiring 90 is connected to the first test wiring 41 of the first test coil 40P. More specifically, the test coil connection wiring 90 is integrated with the first test wiring 41 that constitutes the second end portion 40PB of the first test coil 40P among the multiple first test wirings 41.

The test coil connection wiring 90 is connected to the first test wiring 41 of the second test coil 40Q. More specifically, the test coil connection wiring 90 is integrated with the first test wiring 41 that constitutes the first end portion 40QA of the second test coil 40Q among the multiple first test wirings 41.

The first detection terminal 51, which is electrically connected to the first coil portion 30A, and the second detection terminal 52, which is electrically connected to the second coil portion 30B, are arranged side by side in the X-direction. The first detection terminal 51 is positioned at the same location in the X-direction as the first coil portion 30A. The first detection terminal 51 is positioned at the same location in the X-direction as the portion of the first coil portion 30A closer to the second coil portion 30B. The second detection terminal 52 is positioned at the same location in the X-direction as the second coil portion 30B. The second detection terminal 52 is positioned at the same location in the X-direction as the portion of the second coil portion 30B closer to the first coil portion 30A.

The test terminals 60 include a first test terminal 61 electrically connected to the first test coil 40P and a second test terminal 62 electrically connected to the second test coil 40Q. The first test terminal 61 is electrically connected to the first end portion 40PA of the first test coil 40P. The third connection wiring 63 electrically connects the first test terminal 61 to the first end portion 40PA. The third connection wiring 63 is integrated with the first test wiring 41 that constitutes the first end portion 40PA of the first test coil 40P among the multiple first test wirings 41.

The second test terminal 62 is electrically connected to the second end portion 40QB of the second test coil 40Q. The fourth connection wiring 64 electrically connects the second test terminal 62 to the second end portion 40QB. The fourth connection wiring 64 is integrated with the first test wiring 41 that constitutes the second end portion 40QB of the second test coil 40Q among the multiple first test wirings 41.

The first detection terminal 51 and the second detection terminal 52 are positioned between the first test terminal 61 and the second test terminal 62 in the X-direction. The first test terminal 61 is positioned alongside the first detection terminal 51. The second test terminal 62 is positioned alongside the second detection terminal 52.

According to the modification shown in FIG. 26, the number of turns of the test coil 40 increases, allowing the test current supplied to the test coil 40 to generate a predetermined induced voltage in the detection coil 30 to be reduced. Therefore, the risk of the test coil 40 breaking due to an excessively high test current can be prevented.

In each embodiment, the number of turns of the first coil portion 30A and the second coil portion 30B of the detection coil 30 can be arbitrarily modified. In one example, the number of turns of the first coil portion 30A and the second coil portion 30B may be different from each other.

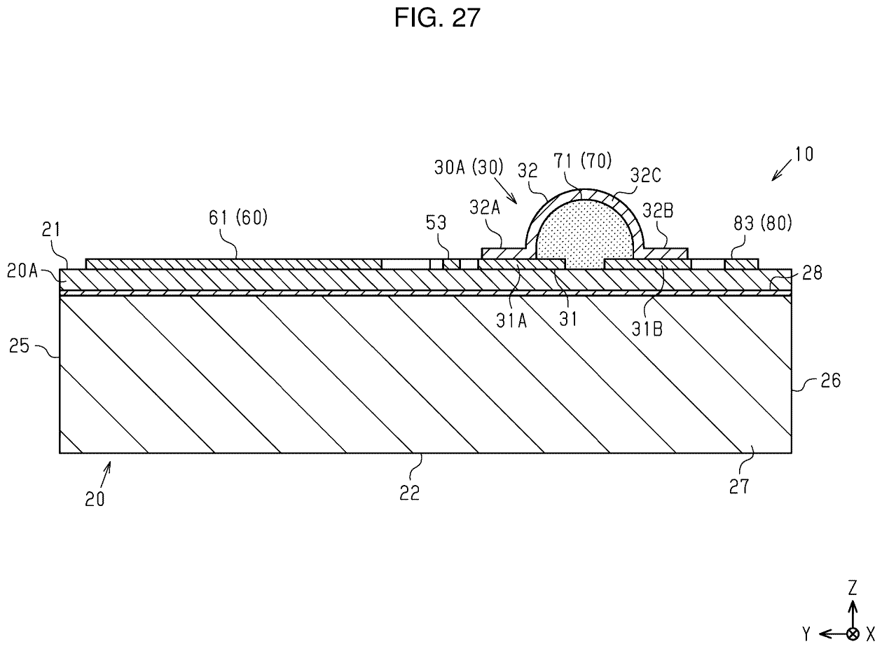

In each embodiment, the configuration of the substrate 20 can be arbitrarily modified. In one example, as shown in FIG. 27, the substrate 20 includes a substrate body 27, an insulating film 28, and a substrate insulating layer 20A. The substrate insulating layer 20A is formed on the upper surface of the insulating film 28. The surface of the substrate insulating layer 20A constitutes the substrate surface 21. In one example, in the first and second embodiments, both the first detection wiring 31 of the detection coil 30 and the first test wiring 41 of the test coil 40 are provided on the surface of the substrate insulating layer 20A (the substrate surface 21). The substrate insulating layer 20A can be composed of an insulating resin such as phenolic resin, or insulating materials such as SiO₂ or SiN. The substrate insulating layer 20A may be composed of two or more insulating layers. If the substrate 20 includes the substrate insulating layer 20A, the insulating film 28 may be omitted.

In each embodiment, the insulating member 70 may be provided separately for the first coil portion 30A, the second coil portion 30B, and the test coil 40. In one example, the insulating member 70 includes a first portion corresponding to the first coil portion 30A, a second portion corresponding to the second coil portion 30B, and a third portion corresponding to the test coil 40. The third portion may be positioned in the X-direction between the first portion and the second portion but spaced apart from them in the X-direction. In one example, the third portion may be provided as a separate component from the first portion and the second portion.

One or more of the various examples described in this specification can be combined within a technically consistent range.

The term “on” as used in this disclosure includes both “on” and “above,” unless the context clearly indicates otherwise. Therefore, for example, the expression “the first element is mounted on the second element” may mean that, in some embodiments, the first element is directly placed in contact with and on the second element. In other embodiments, the first element may be positioned above the second element without direct contact. In other words, the term “on” does not exclude a structure in which another element is formed between the first element and the second element.

The Z-direction as used in this disclosure does not necessarily have to be the vertical direction, nor does it have to align perfectly with the vertical direction. Therefore, various structures according to this disclosure are not limited to cases where “up” and “down” in the Z-direction described in this specification correspond to the vertical “up” and “down.” For example, the X-direction may be the vertical direction, or the Y-direction may be the vertical direction.

### SUPPLEMENTARY NOTES

The technical ideas that can be understood from the above embodiments and the modifications are described below. The reference numerals of the components of the embodiments corresponding to the components described in each additional note are indicated in parentheses. The reference numerals are provided as examples to aid understanding, and the components described in each additional note should not be limited to those indicated by the reference numerals.
<Supplementary Note 1> A magnetic sensor chip (10), including: a detection coil (30) arranged with a first direction (X) as an axial direction thereof; a detection terminal (50) configured to detect an induced voltage generated by the detection coil (30); a test coil (40) disposed at a position spaced apart from the detection coil (30); and a test terminal (60) configured to supply a test current to the test coil (40), wherein the test coil (40) is disposed at a position where the induced voltage is generated in the detection coil (30) when the test current flows through the test coil (40).
<Supplementary Note 2> In the magnetic sensor chip of Additional Note 1, the test coil (40) is disposed at a position spaced apart from the detection coil (30) in the first direction (X).
<Additional Note 3> In the magnetic sensor chip of Supplementary Note 2, when a direction orthogonal to the first direction (X) in a plan view of the magnetic sensor chip is defined as a second direction (Y), both the test terminal (60) and the detection terminal (50) are disposed at positions spaced apart from the test coil (40) and the detection coil (30) in the second direction (Y), and the test terminal (60) and the detection terminal (50) are arranged apart from each other in the first direction (X).
<Supplementary Note 4> In the magnetic sensor chip of Supplementary Note 3, the detection coil (30) includes a first coil portion (30A) and a second coil portion (30B) electrically connected to each other, and the test coil (40), the first coil portion (30A), and the second coil portion (30B) are arranged in the first direction (X).
<Supplementary Note 5> In the magnetic sensor chip of Supplementary Note 4, the test coil (40) is disposed between the first coil portion (30A) and the second coil portion (30B) in the first direction (X).
<Supplementary Note 6> In the magnetic sensor chip of Supplementary Note 5, the detection terminal (50) includes a first detection terminal (51) electrically connected to the first coil portion (30A) and a second detection terminal (52) electrically connected to the second coil portion (30B), wherein the first detection terminal (51) and the second detection terminal (52) are disposed apart from each other in the first direction (X), the test terminal (60) includes a first test terminal (61) electrically connected to a first end portion (40A) of the test coil (40) and a second test terminal (62) electrically connected to a second end portion (40B) of the test coil (40), and both the first test terminal (61) and the second test terminal (62) are disposed between the first detection terminal (51) and the second detection terminal (52) in the first direction (X).
<Supplementary Note 7> In the magnetic sensor chip of Supplementary Note 6, the magnetic sensor chip further includes a first connection wiring (53) that connects the first detection terminal (51) and the first coil portion (30A) and a second connection wiring (54) that connects the second detection terminal (52) and the second coil portion (30B), wherein the first connection wiring (53) is connected to an end portion (30AA) of the first coil portion (30A) on the test coil (40) side, and the second connection wiring (54) is connected to an end portion (30BA) of the second coil portion (30B) on the test coil (40) side.
<Supplementary Note 8> In the magnetic sensor chip of Supplementary Note 7, the magnetic sensor chip further includes a third connection wiring (63) that connects the first test terminal (61) and a first end portion (40A) of the test coil (40) on the first coil portion (30A) side and a fourth connection wiring (64) that connects the second test terminal (62) and a second end portion (40B) of the test coil (40) on the second coil portion (30B) side, wherein both the third connection wiring (63) and the fourth connection wiring (64) are disposed between the first connection wiring (53) and the second connection wiring (54) in the first direction (X).
<Supplementary Note 9> In the magnetic sensor chip of Supplementary Note 4, the first coil portion (30A) is disposed between the test coil (40) and the second coil portion (30B).
<Supplementary Note 10> In the magnetic sensor chip of Supplementary Note 9, both the test terminal (60) and the detection terminal (50) are disposed at positions spaced apart from the test coil (40) and the detection coil (30) in the second direction (Y), the detection terminal (50) includes a first detection terminal (51) electrically connected to the first coil portion (30A) and a second detection terminal (52) electrically connected to the second coil portion (30B), the first detection terminal (51) and the second detection terminal (52) are disposed side by side in the first direction (X), the test terminal (60) includes a first test terminal (61) electrically connected to a first end (40A) of the test coil (40) and a second test terminal (61) electrically connected to a second end (40B) of the test coil (40), and the first detection terminal (51) is disposed between the test terminal (60) and the second detection terminal (52) in the first direction (X).
<Supplementary Note 11> In the magnetic sensor chip of Supplementary Note 4, the test coil (40) includes a first test coil (40P) and a second test coil (40Q) that are spaced apart from each other in the first direction (X), and the first coil portion (30A) and the second coil portion (30B) are disposed between the first test coil (40P) and the second test coil (40Q).
<Supplementary Note 12> In the magnetic sensor chip of Supplementary Note 11, when a direction orthogonal to the first direction (X) in a plan view of the magnetic sensor chip is defined as a second direction (Y), both the test terminal (60) and the detection terminal (50) are disposed at positions spaced apart from the test coil (40) and the detection coil (30) in the second direction (Y), the detection terminal (50) includes a first detection terminal (51) electrically connected to the first coil portion (30A) and a second detection terminal (52) electrically connected to the second coil portion (30B), the first detection terminal (51) and the second detection terminal (52) are disposed side by side in the first direction (X), the test terminal (60) includes a first test terminal (61) electrically connected to an end portion (40PA) of the first test coil (40P) opposite to the first coil portion (30A) and a second test terminal (62) electrically connected to an end portion (40QB) of the second test coil (40Q) opposite to the second coil portion (30B), the first test terminal (61) and the second test terminal (62) are disposed apart from each other in the first direction (X), and the first detection terminal (51) and the second detection terminal (52) are disposed between the first test terminal (61) and the second test terminal (62) in the first direction (X).
<Supplementary Note 13> In the magnetic sensor chip of Supplementary Note 12, the magnetic sensor chip further includes a test coil connection wiring (90) configured to electrically connect the first test coil (40P) and the second test coil (40Q).
<Supplementary Note 14> In the magnetic sensor chip of Supplementary Note 13, the test coil connection wiring (90) is disposed, in the second direction (Y), on the opposite side of the test coil (40) and the detection coil (30) from the test terminal (60) and the detection terminal (50).
<Supplementary Note 15> In the magnetic sensor chip of any one of Supplementary Notes 5 to 8, the magnetic sensor chip further includes a coil connection wiring (80) configured to electrically connect the first coil portion (30A) and the second coil portion (30B).
<Supplementary Note 16> In the magnetic sensor chip of Supplementary Note 15, the coil connection wiring (80) connects an end portion (30AB) of the first coil portion (30A) opposite to the test coil (40) and an end portion (30BB) of the second coil portion (30B) opposite to the test coil (40).
<Supplementary Note 17> In the magnetic sensor chip of Supplementary Note 15 or 16, the coil connection wiring (80) is disposed, in the second direction (Y), on the opposite side of the test coil (40) and the detection coil (30) from the test terminal (60) and the detection terminal (50).
<Supplementary Note 18> In the magnetic sensor chip of any one of Supplementary Notes 1 to 17, the magnetic sensor chip includes a substrate (20) including a substrate surface (21), and the test coil (40) includes a first test wiring (41) provided on the substrate surface (21) and a second test wiring (42) connected to the first test wiring (41).
<Supplementary Note 19> In the magnetic sensor chip of Supplementary Note 18, the detection coil (30) includes a plurality of first detection wirings (31) provided on the substrate surface (21) and arranged apart from each other in the first direction (X), and a plurality of second detection wirings (32) arranged apart from each other in the first direction (X). Each second detection wiring (32) are connected to two first detection wirings (31) that are respectively adjacent to the second detection wiring (32) in the first direction (X).
<Supplementary Note 20> In the magnetic sensor chip of Supplementary Note 19, each of the plurality of first detection wirings (31) extends in a direction intersecting the first direction (X) in a plan view.
<Supplementary Note 21> In the magnetic sensor chip of Supplementary Note 19> or <Supplementary Note 20, the magnetic sensor chip further includes an insulating member (70) in contact with the substrate surface (21) and covering the first test wiring (41) and the plurality of first detection wirings (31), and the second test wiring (42) extends along a surface (71) of the insulating member (70).
<Supplementary Note 22> In the magnetic sensor chip of Supplementary Note 21, the second detection wiring (32) extends along a surface (71) of the insulating member (70).
<Supplementary Note 23> In the magnetic sensor chip of any one of Supplementary Notes 19 to 22, the first detection wiring (31) includes a first end portion (31A) and a second end portion (31B) opposite to the first end portion (31A), the second detection wiring (32) includes a third end portion (32A) connected to the first end portion (31A) and a fourth end portion (32B) opposite to the third end portion (32A) and connected to the second end portion (31B), and a width (W13) of the third end portion (32A) is smaller than a width (W11) of the first end portion (31A).
<Supplementary Note 24> In the magnetic sensor chip of Supplementary Note 23, a length (L13) of the third end portion (32A) is shorter than a length (L11) of the first end portion (31A).
<Supplementary Note 25> In the magnetic sensor chip of Supplementary Note 23 or 24, a width (W14) of the fourth end portion (32B) is smaller than a width (W12) of the second end portion (31B).
<Supplementary Note 26> In the magnetic sensor chip of Supplementary Note 25, a length (L14) of the fourth end portion (32B) is shorter than a length (L12) of the second end portion (31B).
<Supplementary Note 27> In the magnetic sensor chip of any one of Supplementary Notes 19 to 26, the first test wiring (41) includes a first end portion (41A) and a second end portion (41B) opposite to the first end portion (41A), the second test wiring (42) includes a third end portion (42A) connected to the first end portion (41A) and a fourth end portion (42B) opposite to the third end portion (42A) and connected to the second end portion (41B), and a width (W23) of the third end portion (42A) is smaller than a width (W21) of the first end portion (41A).
<Supplementary Note 28> In the magnetic sensor chip of Supplementary Note 27, a length (L23) of the third end portion (42A) is shorter than a length (L21) of the first end portion (41A).
<Supplementary Note 29> In the magnetic sensor chip of Supplementary Note 27 or 28, a width (W24) of the fourth end portion (42B) is smaller than a width (W22) of the second end portion (31B).
<Supplementary Note 30> In the magnetic sensor chip of Supplementary Note 29, a length (L24) of the fourth end portion (42B) is shorter than a length (L22) of the second end portion (31B).
<Supplementary Note 31> In the magnetic sensor chip of Supplementary Note 21, a cross-sectional shape of the insulating member (70) orthogonal to the first direction (X) is an arc shape, trapezoidal shape, or rectangular shape protruding away from the substrate (20).
<Supplementary Note 32> In the magnetic sensor chip of any one of Supplementary Notes 19 to 30, the substrate (20) includes a substrate back surface (22) opposite to the substrate surface (21) and a recess (29) recessed from the substrate surface (21) toward the substrate back surface (22), and the first test wiring (41) and the first detection wiring (31) extend along a surface (29A, 29B) of the recess (29).
<Supplementary Note 33> In the magnetic sensor chip of Supplementary Note 32, the magnetic sensor chip further includes an insulating member (70) embedded in the recess (29) and covering the first test wiring (41) and the plurality of first detection wirings (31), and both the second test wiring (42) and the second detection wiring (32) extend along a surface (71) of the insulating member (70).
<Supplementary Note 34> In the magnetic sensor chip of any one of Supplementary Notes 19 to 33, the first test wiring (41) extends in parallel with the first detection wiring (31) in a plan view, and the second test wiring (42) extends in parallel with the second detection wiring (32) in a plan view.
<Supplementary Note 35> In the magnetic sensor chip of any one of Supplementary Notes 1 to 34, the test coil (40) is arranged with the first direction (X) as an axial direction thereof.
<Supplementary Note 36> In the magnetic sensor chip of Supplementary Note 35, an axis of the test coil (40) is coaxial with an axis of the detection coil (30).
<Supplementary Note 37> In the magnetic sensor chip of any one of Supplementary Notes 4 to 17, a winding direction of the first coil portion (30A) is the same as a winding direction of the second coil portion (30B).
<Supplementary Note 38> In the magnetic sensor chip of any one of Supplementary Notes 1 to 37, the number of turns of the test coil (40) is smaller than the number of turns of the detection coil (30).
<Supplementary Note 39> In the magnetic sensor chip of any one of Supplementary Notes 4 to 17, the number of turns of the test coil (40) is smaller than the number of turns of the first coil portion (30A) and the second coil portion (30B).
<Supplementary Note 40> In the magnetic sensor chip of any one of Supplementary Notes 4 to 17, the number of turns of the first coil portion (30A) is equal to the number of turns of the second coil portion (30B).
<Supplementary Note 41> In the magnetic sensor chip of any one of Supplementary Notes 4 to 17, the number of turns of the first coil portion (30A) is different from the number of turns of the second coil portion (30B).
<Supplementary Note 42> In the magnetic sensor chip of Supplementary Note 38, the number of turns of the test coil (40) is one.
<Supplementary Note 43> In the magnetic sensor chip of Supplementary Note 38, the number of turns of the test coil (40) is two or more.
<Supplementary Note 44> In the magnetic sensor chip of Supplementary Note 38, the number of turns of the test coil (40) is three.
<Supplementary Note 45> A magnetic sensor module (100) comprising: a die pad (110); the magnetic sensor chip (10) according to any one of Supplementary Notes 1> to <Supplementary Note 44> mounted on the die pad (110); a control chip (130) mounted on the die pad (110) and electrically connected individually to the detection terminal (50) and the test terminal (60) of the magnetic sensor chip (10); and an encapsulating resin (140) that seals at least the magnetic sensor chip (10) and the control chip (130).
<Supplementary Note 46> In the magnetic sensor module of Supplementary Note 45, the control chip (130) is configured to supply the test current to the test terminal (60) and detect the induced voltage generated in the detection coil (30) by the test coil (40) through the detection terminal (50) when the test current flows through the test coil (40).

The above description is merely illustrative. Those skilled in the art will recognize that, beyond the components and methods (manufacturing processes) listed for the purpose of describing the technology of the present disclosure, further combinations and substitutions are possible. The present disclosure is intended to encompass all alternatives, modifications, and variations that fall within the scope of the present disclosure including the claims.

What is claimed is:

1. A magnetic sensor chip, comprising:
a detection coil arranged such that an axial direction of the detection coil is a first direction;
a detection terminal configured to detect an induced voltage generated in the detection coil;
a test coil disposed at a position spaced apart from the detection coil; and
a test terminal configured to supply a test current to the test coil,
wherein the test coil is disposed at a position where the induced voltage is generated in the detection coil when the test current flows through the test coil.

2. The magnetic sensor chip according to claim 1, wherein the test coil is disposed at a position spaced apart from the detection coil in the first direction.

3. The magnetic sensor chip according to claim 2, wherein, in a plan view of the magnetic sensor chip, when a direction orthogonal to the first direction is defined as a second direction, both the test terminal and the detection terminal are disposed at positions spaced apart from the test coil and the detection coil in the second direction; and
wherein the test terminal and the detection terminal are disposed apart from each other in the first direction.

4. The magnetic sensor chip according to claim 3, wherein the detection coil includes a first coil portion and a second coil portion electrically connected to each other; and
wherein the test coil, the first coil portion, and the second coil portion are arranged in the first direction.

5. The magnetic sensor chip according to claim 4, wherein the test coil is disposed between the first coil portion and the second coil portion.

6. The magnetic sensor chip according to claim 5, wherein the detection terminal includes:
a first detection terminal electrically connected to the first coil portion; and
a second detection terminal electrically connected to the second coil portion,
wherein the first detection terminal and the second terminal are disposed apart from each other in the first direction;
wherein the test terminal includes:
a first test terminal electrically connected to a first end of the test coil; and
a second test terminal electrically connected to a second end of the test coil, and
wherein both the first test terminal and the second test terminal are disposed between the first detection terminal and the second detection terminal in the first direction.

7. The magnetic sensor chip according to claim 6, further comprising:
a first connection wiring connecting the first detection terminal to the first coil portion; and
a second connection wiring connecting the second detection terminal to the second coil portion,
wherein the first connection wiring is connected to an end of the first coil portion on a test coil side, and
wherein the second connection wiring is connected to an end of the second coil portion on the test coil side.

8. The magnetic sensor chip according to claim 7, further comprising:
a third connection wiring connecting the first test terminal to a first end of the test coil on the first coil portion side; and
a fourth connection wiring connecting the second test terminal to a second end of the test coil on the second coil portion side,
wherein both the third connection wiring and the fourth connection wiring are disposed between the first connection wiring and the second connection wiring in the first direction.

9. The magnetic sensor chip according to claim 4, wherein the first coil portion is disposed between the test coil and the second coil portion in the first direction.

10. The magnetic sensor chip according to claim 9, wherein both the test terminal and the detection terminal are disposed at positions spaced apart from the test coil and the detection coil in the second direction,
wherein the detection terminal includes:
a first detection terminal electrically connected to the first coil portion; and
a second detection terminal electrically connected to the second coil portion,
wherein the first detection terminal and the second detection terminal are arranged side by side in the first direction,
wherein the test terminal includes:
a first test terminal electrically connected to a first end of the test coil; and
a second test terminal electrically connected to a second end of the test coil, and
wherein the first detection terminal is disposed between the test terminal and the second detection terminal in the first direction.

11. The magnetic sensor chip according to claim 1, wherein a total number of turns of the test coil is smaller than a total number of turns of the detection coil.

12. The magnetic sensor chip according to claim 4, further comprising a coil connection wiring electrically connecting the first coil portion and the second coil portion.

13. The magnetic sensor chip according to claim 12, wherein the coil connection wiring connects an end of the first coil portion opposite to the test coil and an end of the second coil portion opposite to the test coil.

14. The magnetic sensor chip according to claim 12, wherein in the second direction, the coil connection wiring is disposed on a side of the test coil and the detection coil opposite from a side where the test terminal and the detection terminal are disposed.

15. The magnetic sensor chip according to claim 1, further comprising a substrate including a substrate surface,
wherein the test coil includes:
a first test wiring provided on the substrate surface, and
a second test wiring connected to the first test wiring.

16. The magnetic sensor chip according to claim 15, wherein the detection coil includes:
a plurality of first detection wirings provided on the substrate surface, extending in a direction intersecting the first direction in a plan view of the magnetic sensor chip and spaced apart from each other in the first direction; and
a plurality of second detection wirings arranged spaced apart from each other in the first direction, each connected to two first detection wirings adjacent to each other in the first direction.

17. The magnetic sensor chip according to claim 16, further comprising an insulating material in contact with the substrate surface and covering the first test wiring and the plurality of first detection wirings,
wherein the second test wiring extends along the surface of the insulating material.

18. The magnetic sensor chip according to claim 17, wherein a cross-sectional shape of the insulating material in a direction orthogonal to the first direction is arc-shaped, trapezoidal, or rectangular that protrudes in a direction away from the substrate.

19. A magnetic sensor module, comprising:
a die pad;
the magnetic sensor chip according to claim 1, mounted on the die pad;
a control chip mounted on the die pad and electrically connected to the detection terminal and the test terminal of the magnetic sensor chip individually; and
a sealing resin that seals at least the magnetic sensor chip and the control chip.

20. The magnetic sensor module according to claim 19, wherein the control chip is configured to supply the test current to the test terminal, and to detect, through the detection terminal, the induced voltage generated in the detection coil by the test coil through which the test current flows.
